(19) United States
(12) Patent Application Publication
(10) Pub. No.: US 2019/0013433 A1
(43) Pub. Date: Jan. 10, 2019

(54) Light Emitting Transistor and Method for Manufacturing the Same

(71) Applicant: LG Display Co., Ltd., Seoul (KR)

(72) Inventors: JungHan KIM, Seoul (KR); GeeSung CHAE, Incheon (KR); HoCheol KANG, Goyang-si (KR); Seungyong NAM, Seoul (KR)

(21) Appl. No.: 15/835,379

(22) Filed: Dec. 7, 2017

(30) Foreign Application Priority Data
Jul. 6, 2017 (KR) 10-2017-0086131
Oct. 27, 2017 (KR) 10-2017-0141083

(51) Int. Cl. H01L 33/00; H01L 33/06; H01L 33/32

(52) U.S. Cl. CPC H01L 33/0041; H01L 33/06; H01L 27/156; H01L 33/0075; H01L 33/32

(57) ABSTRACT

Provided are a light emitting transistor and a method for manufacturing the same. The light emitting transistor includes: a channel layer disposed on a substrate; a first lower pattern disposed in the luminescent area and a second lower pattern disposed to be spaced apart from the first lower pattern in the non-luminescent area, which are disposed on the channel layer; a light emitting layer disposed on the first lower pattern; an upper layer disposed on the light emitting layer; a first electrode disposed on the upper layer; an insulating layer disposed between the first lower pattern and the second lower pattern in the non-luminescent area; a second electrode disposed on the insulating layer; and a third electrode disposed on the second lower pattern to concentrate a light emitting diode and a transistor, thereby implementing a microdisplay.

### CROSS-REFERENCE TO RELATED APPLICATION

This application claims priority to Republic of Korea Patent Application No. 10-2017-0086131 filed on Jul. 6, 2017; and Republic of Korea Patent Application No. 10-2017-0141083 filed on Oct. 27, 2017, all of which are incorporated herein by reference.

### BACKGROUND

### Field

The present disclosure relates to a light emitting transistor and a method for manufacturing the same, and more particularly, to a light emitting transistor and a method for manufacturing the same which can implement a microdisplay.

### Description of the Related Art

A light emitting diode LED which is a semiconductor light emitting element emits light energy of various wavelengths by applying an electrical signal using characteristics of a compound semiconductor. Currently, a commercially available light emitting diode element adopts a process of a compound semiconductor in which a p-type semiconductor (group III) having holes is bonded to an n-type semiconductor (group V) having electrons as a majority of carriers.

In particular, since a group-III element including a nitride has excellent thermal stability and a direct transition type energy band structure, the group-III element is advantageous in downsizing, thinning, and weight reduction as a high efficiency low-power element. Further, since the light emitting diode element has a long lifetime and does not require preheating time, and has a characteristic that lighting and extinction speeds are very fast, the light emitting diode element has attracted more attention while being utilized in a backlight module of a large-area liquid crystal display LCD by substituting for an incandescent lamp or a fluorescent lamp in the related art.

In recent years, a display device in which a transistor element is connected to the light emitting diode element has been researched for active matrix AM driving of the light emitting diode element.

### SUMMARY

Embodiment relate to a light emitting transistor including a luminescent area and a non-luminescent area. The light emitting transistor includes a channel layer, a first lower pattern, a second lower pattern, a light emitting layer, an upper layer, a first electrode, an insulating layer, a second electrode, and a third electrode. The channel layer is on a substrate. The first lower pattern is in the luminescent area. The second lower pattern is disposed to be spaced apart from the first lower pattern in the non-luminescent area. The light emitting layer is on the first lower pattern . The upper layer is on the light emitting layer . The first electrode is on the upper layer. The insulating layer is between the first lower pattern and the second lower pattern in the non-luminescent area. The second electrode is on the insulating layer. The third electrode is on the second lower pattern.

In one or more embodiments, the light emtting transistor further includes a channel layer. The channel layer is an intrinsic semiconductor layer. The first lower pattern and second lower pattern are n-type semiconductor layer. The light emitting layer is a multiple quantum well layer. The upper layer is a p-type semiconductor layer.

In one or more embodiments, the channel layer is an undoped gallium nitride layer, and the first lower pattern and second lower pattern are n-type gallium nitride layer.

In one or more embodiments, a dimension of the luminescent area is 65% or more of a sum of the dimension of the luminescent area and a dimension of the non-luminescent area.

In one or more embodiments, a distance from an edge of the luminescent area to a center of the luminescent area is less than 30 μm.

In one or more embodiments, a thickness of the insulating layer is less than 0.1 μm.

In one or more embodiments, a distance between the first lower pattern and the second lower pattern is 1 μm or more.

In one or more embodiments, a thickness of the channel layer is 1 to 4 μm.

In one or more embodiments, the light emtting transistor further includes a channel auxiliary layer between the substrate and the channel layer. The channel auxiliary layer is of a p-type semiconductor layer.

In one or more embodiments, a p-doping concentration of the channel auxiliary layer is 10¹⁹ to 10²⁰ cm⁻³.

In one or more embodiments, the light emtting transistor further includes a buffer layer between the channel auxiliary layer and the substrate. The p-doping concentration of the buffer layer is lower than the p-doping concentration of the channel auxiliary layer.

Embodiments also relate to a light emitting structure including a channel layer, a first semiconductor layer, an insulating layer, a light emtting layer, a second semiconductor layer, and a gate layer. The first semiconductor layer is of a first doping polarity on the channel layer. The first semiconductor layer is formed with a trench extending towards the channel layer. The insulating layer is in the trench and on at least part of the channel layer. The light emitting layer is on the first semiconductor layer and is surrounded by the trench. The second semiconductor layer is of a second doping polarity opposite to the first doping polarity on the light emitting layer. The second semiconductor is of a transparent material. The gate layer is over at least a portion of the insulating layer in the trench. The gate layer is applied with voltage to forma channel in the channel layer to enable flow of current in the first semiconductor layer for activating the light emitting layer.

In one or more embodiment, the light emitting structure further includes a substrate under the channel layer, a first electrode on the second semiconductor layer, and a second electrode on the first semiconductor layer outside the trench and separated from the gate layer. The current is caused by a voltage difference between the first electrode and the second electrode.

In one or more embodiment, the insulating layer extends between the first electrode and the second electrode.

In one or more embodiments, the first electrode and the gate layer are separated in a direction parallel to a direction in which a surface of the channel layer extends.

In one or more embodiments, the light emitting structure further includes a channel auxiliary layer between the substrate and the channel layer. The channel auxiliary layer prevents leakage current.

In one or more embodiments, the channel auxiliary layer is a semiconductor of the second doping polarity.

In one or more embodiments, the channel layer is an undoped semiconductor.

In one or more embodiments, the gate layer in conjunction with a part of the insulating layer and a portion of the channel layer below the gate layer forms a transistor.

Embodiments also relate to a method for manufacturing a light emitting structure. A channel layer is formed on a substrate. A first semiconductor layer of a first doping polarity is formed on the channel layer. A light emitting layer is formed on the first semiconductor layer. A second semiconductor layer of a second oping polarity opposite to the first doping polarity is formed on the light emitting layer. A portion of the first semiconductor layer , The portion of the light emitting layer, and a portion of the second semiconductor layer are removed to define a non-luminescent area. A channel area of the channel layer in the non-luminescent area is exposed. An insulating layer to cover the exposed channel area is formed. Agate layer is formed in the channel area and on at least a portion of the first seminconductor layer in ther non-luminescent area.

In one or more embodiments, a first electrode is formed on the second semiconductor layer. A second electrode is formed on the first semiconductor layer in the non-luminescent area.

In one or more embodiments, a channel auxiliary layer is formed on the substrate before forming the channel layer.

In one or more embodiments, a buffer layer is formed on the substrate before forming the channel auxiliary layer.

In one or more embodiments, the channel layer, the first semiconductor layer and the second semiconductor layer are formed in the same reaction chamber.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a light emitting transistor according to an exemplary embodiment of the present disclosure;

FIG. 2 is a cross-sectional view taken along line II-II′ of FIG. 1;

FIGS. 3A to 3C are graphs for describing a switching characteristic of the light emitting transistor according to the exemplary embodiment of the present disclosure;

FIG. 4 is a plan view of a light emitting transistor according to another exemplary embodiment of the present disclosure;

FIGS. 5A to 5D are graphs illustrating a switching characteristic of a light emitting transistor according to another exemplary embodiment of the present disclosure;

FIG. 6 is a flowchart illustrating a method for manufacturing a light emitting transistor according to an exemplary embodiment of the present disclosure;

FIGS. 7A to 7H are process cross-sectional views illustrating the method for manufacturing a light emitting transistor according to the exemplary embodiment of the present disclosure;

FIG. 7I is a detailed cross-sectional view of a trench, according to one embodiment of the present disclosure;

FIG. 7J is a detailed cross-sectional view of a trench, according to another embodiment of the present disclosure;

FIG. 8 is a flowchart illustrating a method for manufacturing a light emitting transistor according to another exemplary embodiment of the present disclosure;

FIGS. 9A to 9H are process cross-sectional views for illustrating the method for manufacturing a light emitting transistor according to another exemplary embodiment of the present disclosure;

FIG. 9I is a detailed cross-sectional view of a trench, according to one embodiment of the present disclosure; and

FIG. 9J is a detailed cross-sectional view of a trench, according to another embodiment of the present disclosure.

### DETAILED DESCRIPTION OF THE EMBODIMENT

Advantages and features of the present disclosure, and methods for accomplishing the same will be more clearly understood from exemplary embodiments described below with reference to the accompanying drawings. However, the present disclosure is not limited to the following exemplary embodiments but may be implemented in various different forms. The exemplary embodiments are provided only to complete disclosure of the present disclosure and to fully provide a person having ordinary skill in the art to which the present disclosure pertains with the category of the disclosure, and the present disclosure will be defined by the appended claims.

The shapes, sizes, ratios, angles, numbers, and the like illustrated in the accompanying drawings for describing the exemplary embodiments of the present disclosure are merely examples, and the present disclosure is not limited thereto. Further, in the following description, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is referred to as being “on” another element or layer, it may be directly on the other element or layer, or intervening elements or layers may be present.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Throughout the whole specification, the same reference numerals denote the same elements.

Since size and thickness of each component illustrated in the drawings are represented for convenience in explanation, the present disclosure is not necessarily limited to the illustrated size and thickness of each component.

The features of various embodiments of the present disclosure can be partially or entirely bonded to or combined with each other and can be interlocked and operated in technically various ways, and the embodiments can be carried out independently of or in association with each other.

Hereinafter, various exemplary embodiments of the present disclosure will be described in detail with reference to the accompanying drawings.

Manufacturing a light emitting diode element and corresponding a transistor by separate processes accompany the following problems. First, in order to maintain a predetermined level of process yield, the light-emitting diode element and the transistor element is manufactured with certain distance between them. Asa result, an area where the light emitting diode elements emit light in a display device is relatively reduced, therefore, luminous efficiency of the display device deteriorates. In order to realize a microdisplay in which the size of each pixel is a micro unit, the light emitting diode element and the transistor element of each pixel are densly populated. However, if the light emitting diode element and the transistor element are manufactured through separate processes, the light emitting diode element and the transistor element of each pixel may not be densly populated.

Second, when the light emitting element and the transistor element are manufactured by separate processes, a plurality of chambers for manufacturing the light emitting diode element and the transistor element, respectively is required. When the display device is manufactured by using the plurality of chambers as described above, additional processes such as a vacuuming process and a cleaning process while the plurality of chambers moves are added. The addition of processes complicates the manufacturing process and deteriorates the process yield.

Accordingly, embodiments relate to a light emitting transistor which can increase the concentration of the light emitting diodes and transistors, and a method for manufacturing the light emitting transistor with a thin film grown on the same reaction chamber.

Embodiments also relate to providing a light emitting transistor with reduced leakage current and a method for manufacturing the same.

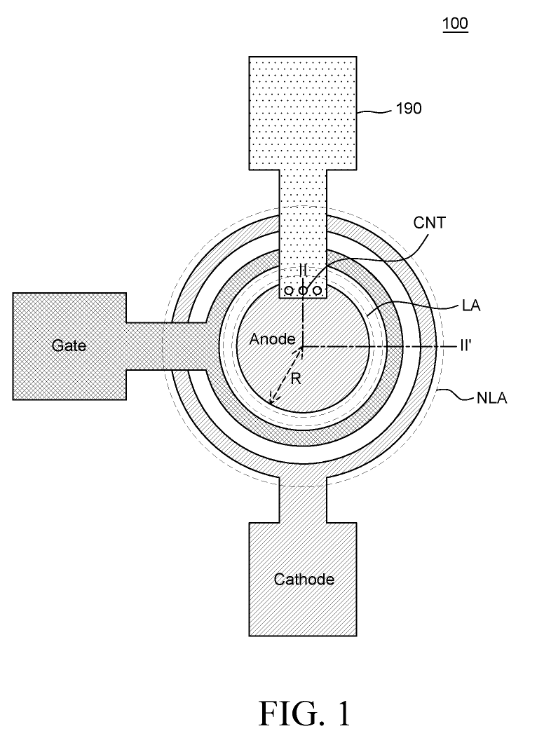

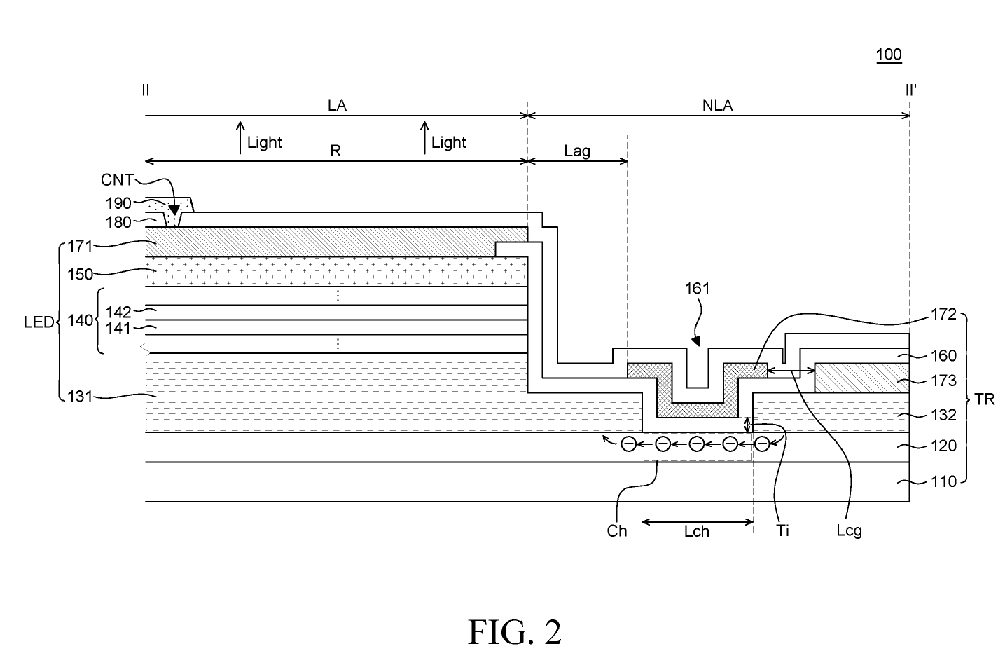

FIG. 1 is a plan view of a light emitting transistor according to an exemplary embodiment of the present disclosure and FIG. 2 is a cross-sectional view taken along line II-II′ of FIG. 1. As illustrated in FIG. 1, the light emitting transistor 100 according to the exemplary embodiment of the present disclosure includes a luminescent area LA in which light is emitted and a non-luminescent area NLA in which the light is not emitted.

In addition, referring to FIG. 2, a light emitting diode LED is disposed in the luminescent area LA, which includes a first lower pattern 131, a light emitting layer 140, an upper layer 150, and a first electrode 171. And, a connecting electrode 190 is disposed in the luminescent area LA, which contacts a first lower pattern 131 through a contact hole CNT of a passivation layer 180 interposed between a first lower pattern 131 and a conneting electrode 190. Further, a transistor TR is disposed in the non-luminescent area NLA, which includes a channel layer 120, a second lower pattern 132, an insulating layer 160, a second electrode 172, and a third electrode 173.

In detail, the third electrode 173 is a cathode electrode and a data signal for determining a degree of light emission of the light emitting transistor 100 may be applied to the third electrode 173. In addition, the second electrode 172 is a gate electrode and a gate signal for determining switching of the transistor TR may be applied to the second electrode 172. Further, the first electrode 171 is an anode electrode and a common signal may be applied to the first electrode 171.

The area ratio of the luminescent area LA to an entire area including the luminescent area LA and the non-luminescent area NLA of the light emitting transistor 100 may be 65% or more. As described above, by setting the area ratio of the luminescent area LA, a luminescent dimension of the light emitting transistor 100 is increased to enhance luminescent efficiency of the light emitting transistor 100 according to the exemplary embodiment of the present disclosure.

In addition, a radius R of the luminescent area LA having a circular shape may be 30 μm or less. That is, a length from the center of the luminescent area LA to an edge of the luminescent area may be 30 μm or less. The radius R of the luminescent area LA is set to implement a microdisplay by using the light emitting transistor 100 according to the exemplary embodiment of the present disclosure. Further, the light emitting transistor 100 having the circular shape is illustrated in FIG. 1, but is not limited thereto and the light emitting transistor 100 may have various shapes such as an elliptical shape, a rectangle shape, and a polygonal shape.

As illustrated in FIG. 2, the light emitting transistor 100 according to the exemplary embodiment of the present disclosure may include the light emitting diode LED disposed in the luminescent area LA on a substrate 110 and the transistor TR disposed in the non-luminescent area NLA on a substrate 110.

The light emitting diode LED includes the first lower pattern 131, the light emitting layer 140, the upper layer 150, the first electrode 171, the passivation layer 180, and the connecting electrode 190 which are sequentially stacked and the transistor TR includes the channel layer 120, the second lower pattern 132, the third electrode 173, the insulating layer 160, and the second electrode 172 which are sequentially stacked.

Hereinafter, the light emitting transistor 100 according to the exemplary embodiment of the present disclosure will be described for each layer. In addition, a growth method of the substrate 110 and each layer of the light emitting transistor 100 according to the exemplary embodiment of the present disclosure maybe implemented through methods including molecular beam Epitaxy MBE, plasma enhanced chemical Vapor Deposition PECVD, vapor phase epitaxy VPE, and the like in addition to metal organic chemical vapor deposition MOCVD in the related art.

The substrate 110 is used for growing a gallium nitride GaN layer which is a channel layer 120 and as the substrate 110, a gallium nitride GaN substrate 110 that is ideal for a nitride based light emitting diode LED is preferably used. However, there is a disadvantage in that it is difficult to manufacture a single crystal substrate 110 using gallium nitride GaN and a unit price is high. As a result, the substrate 110 may be constituted by sapphire, silicon Si, silicon carbide SiC, gallium arsenide GaAs, and zinc oxide ZnO which are relatively easy to obtain and have a low unit price.

The channel layer 120 is disposed on a front surface of the substrate 110. The channel layer 120 may be disposed in the entirety of the luminescent area LA and the non-luminescent area NLA and the channel layer 120 may be an intrinsic semiconductor layer having a thickness of 1 to 4 μm. Specifically, the channel layer 120 may be an undoped gallium nitride GaN u-GaN layer. However, the channel layer 120 is not limited thereto and the channel layer 120 may be doped at a predetermined level in order to improve a switching characteristic of the light emitting transistor 100 according to the exemplary embodiment of the present disclosure.

The channel layer 120 disposed in the luminescent area LA may serve as a buffer layer for supplementing a characteristic of the substrate 110. More specifically, when the first lower pattern 131 which is an epitaxial Epi layer is directly grown on the substrate 110 made of silicon carbide SiC, or the like, it is difficult to manufacture a high-quality light emitting diode 100 by lattice mismatching, and as a result, in order to overcome the difficulty, the channel layer 120 is disposed between the substrate 110 of the luminescent area LA and the first lower pattern 131.

In addition, a channel area Ch of the transistor TR may be formed in the channel layer 120 disposed in the non-luminescent area NLA. As described below, the channel layer 120 disposed in the non-luminescent area NLA is electrically connected with the first lower pattern 131 and the second lower pattern 132 and current flows through the channel area Ch of the layer 120 formed by turning on the transistor TR.

In addition, a high-crystallinity gallium nitride u-GaN layer may be disposed in an upper part of the channel layer 120 by growing under a high temperature and high pressure condition toward the upper part of the channel layer 120. Therefore, crystallinity of the channel area Ch of the transistor TR may be increased. As a result, a current amount which flows through the channel area Ch increases to enhance the switching characteristic of the light emitting transistor 100 according to the exemplary embodiment of the present disclosure.

The thickness of the channel layer 120 may be set to 1 to 4 μm to reduce leakage current when the transistor TR is turned off. In this way, the switching characteristic of the transistor TR may be enhanced.

The first lower pattern 131 is disposed on an upper surface of the channel layer 120 in a vertical direction and disposed in the luminescent area LA in a horizontal direction. In addition, the second lower pattern 132 is disposed on the upper surface of the channel layer 120 in the vertical direction and disposed in the non-luminescent area NLA to be spaced apart from the first lower pattern 131 in the horizontal direction. That is, the first lower pattern 131 and the second lower pattern 132 are formed on the same layer, but may be disposed to be spaced apart from each other by a predetermined interval in the luminescent area LA and the non-luminescent area NLA, respectively.

The part of the channel layer 120 in a trench 161 is exposed as large as the interval by which the first lower pattern 131 and the second lower pattern 132 are spaced apart from each other and the channel area Ch is formed in a part of the channel layer 120 which is exposed as such. That is, the trench 161 of a length Lch is formed between the first lower pattern 131 and the second lower pattern 132. The width Lch of the trench 161 may be 1 μm or more. That is, the spacing interval of the first lower pattern 131 and the second lower pattern 132 may be 1 μm or more. The length Lch of the channel area Ch is set as such to enhance the switching characteristic of the transistor TR.

In addition, each of the first lower pattern 131 and the second lower pattern 132 maybe an n-type semiconductor layer having a thickness of 2 to 4 μm and specifically, each of the first lower pattern 131 and the second lower pattern 132 may be an n-type GaN n-GaN layer. Further, an n-doping concentration of each of the first lower pattern 131 and the second lower pattern 132 may be 10¹⁷ to 10¹⁸ cm⁻³.

The first lower pattern 131 is disposed in the luminescent area LA to supply electrons to the light emitting layer 140 to be described below and the second lower pattern 132 is disposed in the non-luminescent area NLA and electrically connected to the channel area Ch to serve as an ohmic contact layer of the transistor TR, which enhances an ohmic contact characteristics and supplies carriers to the channel area Ch.

The light emitting layer 140 is disposed on the first lower pattern 131 of the luminescent area LA to generate light. Specifically, the light emitting layer 140 rebinds the electrons received from the first lower pattern 131 described above and holes received from the upper layer 150 to be described below to serve to convert extra energy into light. The light emitting layer 140 may have a quantum well QW structure in the related art or a multiple quantum well MQW structure including a plurality of well layers 141 and barrier layers 142 in order to increase efficiency and allow a wavelength of a band which is required to be obtained by controlling compositions and thicknesses of the well layer 141 and the barrier layer 142. Specifically, the well layer 142 may be the gallium nitride u-GaN layer, and the barrier layer 142 may be the indium gallium nitride InGaN layer.

The upper layer 150 is disposed on the light emitting layer 140 in the luminescent area LA to serve to supply the holes to the light emitting layer 140. The upper layer 150 may be a p-type semiconductor layer which may supply the holes to the light emitting layer 140 and specifically, the upper layer 150 may be a p-type GaN p-GaN layer.

The first electrode 171 may be disposed on the upper layer 150 in the luminescent area LA and the first electrode 171 as the anode electrode may be applied with a common signal. Since the first electrode 171 is disposed in the luminescent area LA, the first electrode 171 may be a transparent electrode or a metallic thin film which may transmit the light generated by the light emitting layer 140.

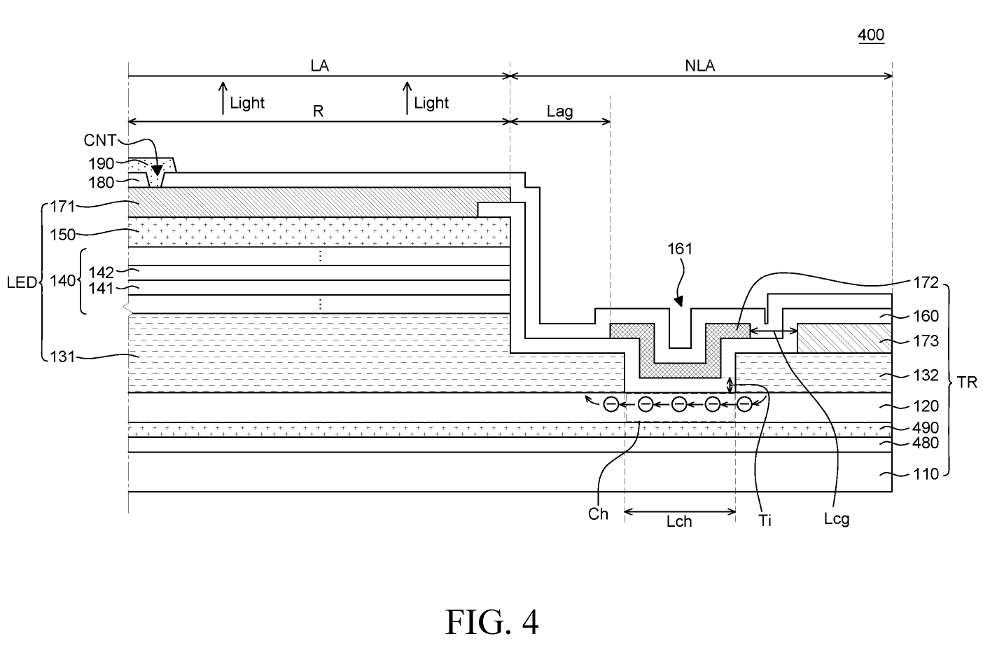

The passivation layer 180 is disposed on on the first electrode 171, the insulating layer 160, and the second electrode 172. The passivation layer 180 may be disposed in the entirety of the luminescent area LA. the non-luminescent area NLA. As illustrated in FIG. 4, the passivation layer 180 includes the contact hole CNT to expose the first electrode 171 through the contact hole CNT. The passivation layer 180 may be made of an organic insulation material or an inorganic insulation material, and the inorganic insulation material may be composed of one of Al₂O₃, ZrO₂, HfO₂, TiO₂, ZnO, Y₂O₃, CeO₂, Ta₂O₅, La₂O₅, Nb₂O₅, SiO₂, SiNx, and AlN and the organic insulation material may be composed of benzocyclobutene BCB and acrylic resin.

The connecting electrode 190 may be disposed on the passivation layer 180 in the luminescent area LA. And, The connecting electrode 190 may be in connection with the first electrode 171 through the contact hole CNT of the passivation layer 180. The connecting layer 190 may be formed as a same material with at least one of the first electrod 171, the second electrode 172, and the third electrode 173.

The third electrode 173 may be disposed on the second lower pattern 132 in the non-luminescent area NLA and the third electrode 172 as the cathode electrode may be applied with a data signal. The amount of the current which flows in the channel area Ch may be controlled by using the data signal.

The insulating layer 160 is disposed to cover the channel layer 120 exposed between the first lower pattern 131 and the second lower pattern 132 in the non-luminescent area NLA. And, The insulating layer 160 may be disposed to cover the third electrode 173. The insulating layer 160 is disposed to cover the upper surface of the channel area Ch to serve to electrically isolate the channel area Ch from the second electrode 172 to be described below. And, The insulating layer 160 may be disposed to cover the third electrode 173 to serve to electrically isolate the third electrode 173 from the second electrode 172 to be described below.

The insulating layer 160 also extends on the second lower pattern 132 and the side surfaces of the first lower pattern 131, the light emtting layer 140, and the upper layer 150, as illustrated in FIG. 4. Such coverage of the insulating layer 160 over the side surfaces is advantageous, among other reasons, because the current flow in a vertical direction across the different layers of the light emitting diode LED may be reduced or prevented. By removing the current flow in the vertical direction, the leakage current in the light emitting diode LED may be reduced and the characteristics of the light emitting diodeLED may be improved.

The insulating layer 160 may be made of an organic insulation material or an inorganic insulation material as an insulation material, and the inorganic insulation material may be composed of one of Al₂O₃, ZrO₂, HfO₂, TiO₂, ZnO, Y₂O₃, CeO₂, Ta₂O₅, La₂O₅, Nb₂O₅, SiO₂, SiNx, and AlN and the organic insulation material may be composed of benzocyclobutene BCB and acrylic resin.

In addition, a thickness Ti of the insulating layer 160 may be within 0.1 μm in order to enhance the switching characteristic of the transistor TR. Detailed contents regarding the characteristic of the transistor TR will be described later.

The second electrode 172 may be disposed on the insulating layer 160 in the non-luminescent area NLA and the second electrode 172 as the gate electrode may be applied with a gate signal. The transistor TR is turned on or turned off by the gate signal. That is, when a high-level gate signal is applied, the transistor TR is turned on, and as a result, the channel area Ch is formed in the channel layer 120 and the current flows in the channel area Ch. However, when a low-level gate signal is applied, the transistor TR is turned off, and as a result, the channel area Ch disappears in the channel layer 120 and no current thus flows.

The third electrode 173 maybe disposed on the second lower pattern 132 in the non-luminescent area NLA and the third electrode 173 as the cathode electrode may be applied with a data signal. The amount of the current which flows in the channel area Ch may be controlled by using the data signal.

The second electrode 172 and the third electrode 173 may be made of different metallic materials including silver Ag, Ag alloy, Cu, copper alloy, aluminum Al, aluminum alloy, silver Ag, aluminum-neodymium, titanium Ti, titanium alloy, molybdenum Mo, molybdenum alloy and the like.

In addition, each of a horizontal spacing distance Lag of the first electrode 171 and the second electrode 172 and a spacing distance Lcg of the second electrode 172 and the third electrode 173 maybe 2 μm or more . As described above, spacing distances among the first electrode 171, the second electrode 172, and the third electrode 173 are set to reduce interference of signals applied to the respective electrodes 171, 172, and 173.

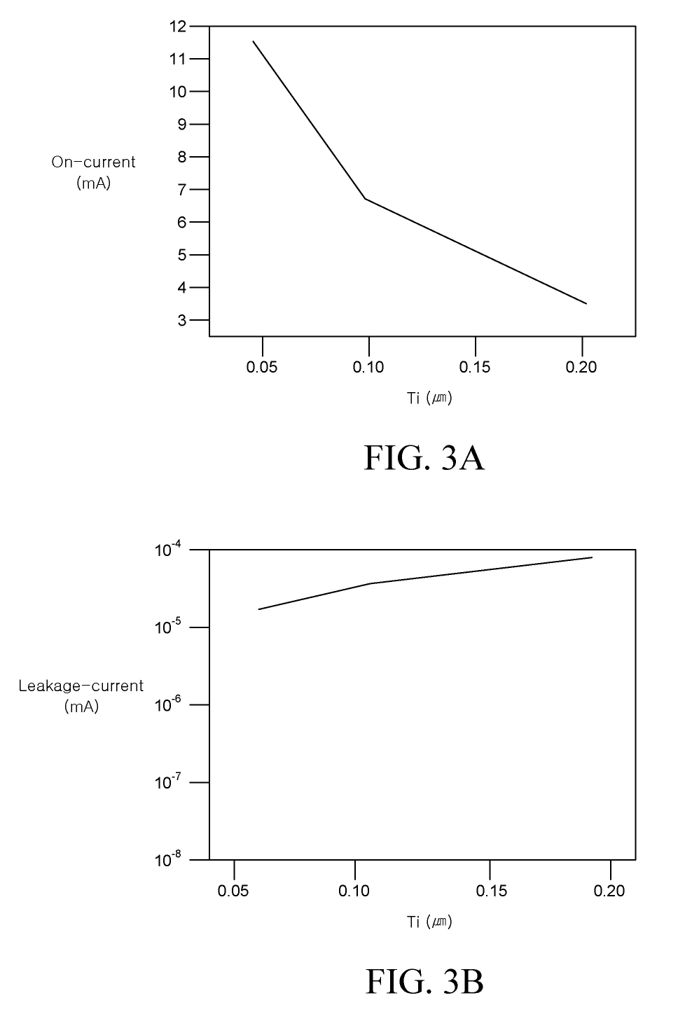

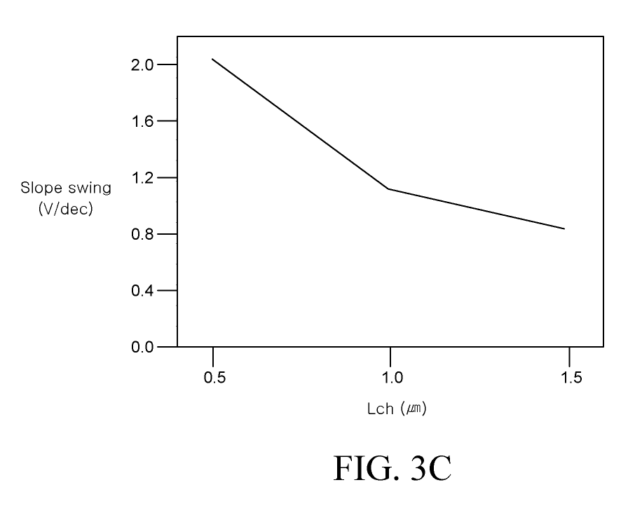

Hereinafter, a driving characteristic and the switching characteristic of the light emitting transistor according to the present disclosure will be described in detail with reference to FIGS. 2 through 3C.

Driving of the light emitting transistor 100 according to the exemplary embodiment of the present disclosure is generally divided into a switching operation of the transistor TR and a light emitting operation of the light emitting diode LED.

First, the switching operation of the transistor TR is described below. When the high-level gate signal is applied to the second electrode 172, the transistor TR is turned on, and as a result, the channel area Ch is formed in the channel layer 120. In addition, the electrons move from the second lower pattern 132 electrically connected with the third electrode 173 to the first lower pattern 131 electrically connected with the second electrode 172 through the channel area Ch due to a potential difference of the second electrode 172 and the third electrode 173. As described above, when the transistor TR is turned on, the current flows from the first lower pattern 131 to the second lower pattern 132 based on the holes .

As described above, when the transistor TR is turned on and the current flows in the first lower pattern 131 and the electrons are distributed, the electrons move to the light emitting layer 140 through the first lower pattern 131. In addition, the holes are transferred in the upper layer 150 electrically connected with the first electrode 171 and the holes move to the light emitting layer 140. Further, in the light emitting layer 140, the electrons received from the first lower pattern 131 and the holes received from the upper layer 150 are recombined to convert extra energy into light.

Contrary to this, when the low-level gate signal is applied, the transistor TR is turned off, and as a result, the channel area Ch disappears in the channel layer 120 and no current flows. Therefore, the electrons are not distributed in the first lower pattern 131, and as a result, the light is not converted in the light emitting layer 140.

FIGS. 3A to 3C are simulation graphs illustrating a switching characteristic of the light emitting transistor according to the exemplary embodiment of the present disclosure. Specifically, FIG. 3A is a graph of on-current which flows in the channel area Ch when the transistor TR is turned on depending on the thickness Ti of the insulating layer 160. FIG. 3B is a graph of leakage current which flows in the channel area Ch when the transistor TR is turned off depending on the thickness Ti of the insulating layer 160. FIG. 3C is a graph of slope swing SS of the transistor TR depending on the length Lch of the channel area Ch. The slope swing SS means a reciprocal number of an inflection point slope in a log graph of voltage-current of the transistor TR. The smaller a slope swing SS value, the better the switching characteristic of the transistor TR.

In addition, the radius R of the luminescent area LA is 20 μm and the n-doping concentration of each of the first lower pattern 131 and the second lower pattern 132 is set to 10¹⁸ cm⁻³ and the thickness of each of the first lower pattern 131 and the second lower pattern 132 is set to 4 μm.

Referring to FIG. 3A, when the width of the trench 161 Lch is set to 1.5 μm, an increase rate of the current when the thickness Ti of the insulating layer 160 is from 0.1 to 0.05 μm is relatively higher than the increase rate of the current when the thickness Ti of the insulating layer 160 is from 0.2 to 0.1 μm.

In addition, referring to FIG. 3B, when the width of the trench 161 Lch is set to 1.5 μm, a decrease rate of the leakage current when the thickness Ti of the insulating layer 160 is from 0.1 to 0.05 μm is relatively lower than the decrease rate of the leakage current when the thickness Ti of the insulating layer 160 is from 0.2 to 0.1 μm.

When the on-current is increased, the light extraction efficiency can be improved. The decrease in the leakage current prevents turning on of the light emitting transistor during turn off times of the light emitting transistor and prevent loss of power during turn off times. Therefore, the switching characteristic of the transistor TR is enhanced as the amount of the on-current when the transistor TR is turned on is more and the amount of the leakage current when the transistor TR is turned off is smaller.

Accordingly, referring to FIGS. 3A and 3B, when the thickness Ti of the insulating layer 160 is 0.1 μm or less, it can be seen that the switching characteristic of the transistor TR is enhanced.

In addition, referring to FIG. 3C, it can be seen that when the thickness Ti of the insulating layer 160 is 0.05 μm, the slope swing SS value decreases when the length Lch of the channel area Ch is from 1 to 1.5 μm. Therefore, it can be seen that when the length Lch of the channel area Ch is 1 μm or more, the switching characteristic is enhanced.

The thickness and the length of each component of the light emitting transistor 100 according to the exemplary embodiment of the present disclosure are controlled as described above to enhance the switching characteristic of the light emitting transistor 100 according to the exemplary embodiment of the present disclosure.

As described above, in the light emitting transistor 100 according to the exemplary embodiment of the present disclosure, the light emitting diode LED and the transistor TR may be manufactured through the same manufacturing process in one substrate 110. As a result, the light emitting diode LED and the transistor TR may be more densly populated.

Hereinafter, a light emitting transistor 400 according to another exemplary embodiment of the present disclosure will be described with reference to FIG. 4. However, duplicated contents with the light emitting transistor 100 according to the exemplary embodiment of the present disclosure will be omitted.

FIG. 4 is a plan view of a light emitting transistor according to another exemplary embodiment of the present disclosure. The light emitting transistor 400 according to another exemplary embodiment of the present disclosure includes a buffer layer 480 on the substrate 110 and a channel auxiliary layer 490 disposed on the buffer layer 480.

The buffer layer 480 is disposed between the substrate 110 and the channel auxiliary layer 490 to supplement the characteristic of the substrate 110. More specifically, when the channel auxiliary layer 490 as the epitaxial Epi layer is directly grown on the silicon carbide SiC substrate 110, it is difficult to manufacture a high-quality element due to lattice mismatching, and as a result, in order to overcome the difficulty, the buffer layer 480 is disposed on the substrate 110.

The buffer layer 480 maybe p-doped with a concentration lower than a p-doping concentration of the channel auxiliary layer 490 for the lattice matching with the channel auxiliary layer 490 and more specifically, the buffer layer 480 may be the undoped gallium nitride u-GaN layer which is the intrinsic semiconductor.

In addition, a more crystallized gallium nitride u-GaN layer may be disposed by growing under the high temperature and high pressure condition toward the upper part of the buffer layer 480.

The channel auxiliary layer 490 is disposed between the buffer layer 480 and the channel layer 120 to reduce the leakage current which flows in the channel area Ch when the transistor TR is turned off.

In this regard, when the transistor TR is turned off, the channel area Ch disappears and no current flows. However, even though the transistor TR is turned off, the channel area Ch remains in a part of the channel layer 120 adjacent to the substrate 110 due to a spontaneous-polarization phenomenon of gallium nitride GaN constituting the channel layer 120. The leakage current flows due to the channel area Ch which remains as described above, which hinders the switching characteristic of the transistor TR.

The channel auxiliary layer 490 suppresses the remaining of the channel area Ch which occurs due to the spon taneous-polarization phenomenon of gallium nitride GaN to serve to reduce the leakage current.

The channel auxiliary layer 490 may be the p-type semiconductor layer. Specifically, the channel auxiliary layer 490 may be the p-type gallium nitride p-GaN layer having the concentration of 10¹⁹ to 10²⁰ cm⁻³. In addition, the channel auxiliary layer 490 is preferably grown with the thickness of 1 μm, but is not limited thereto.

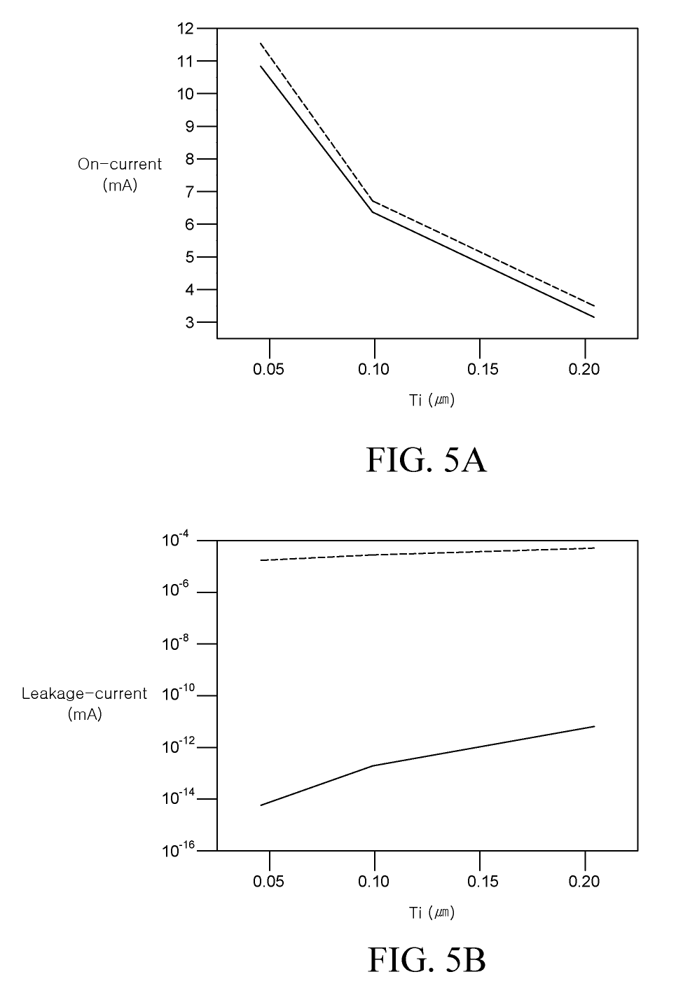

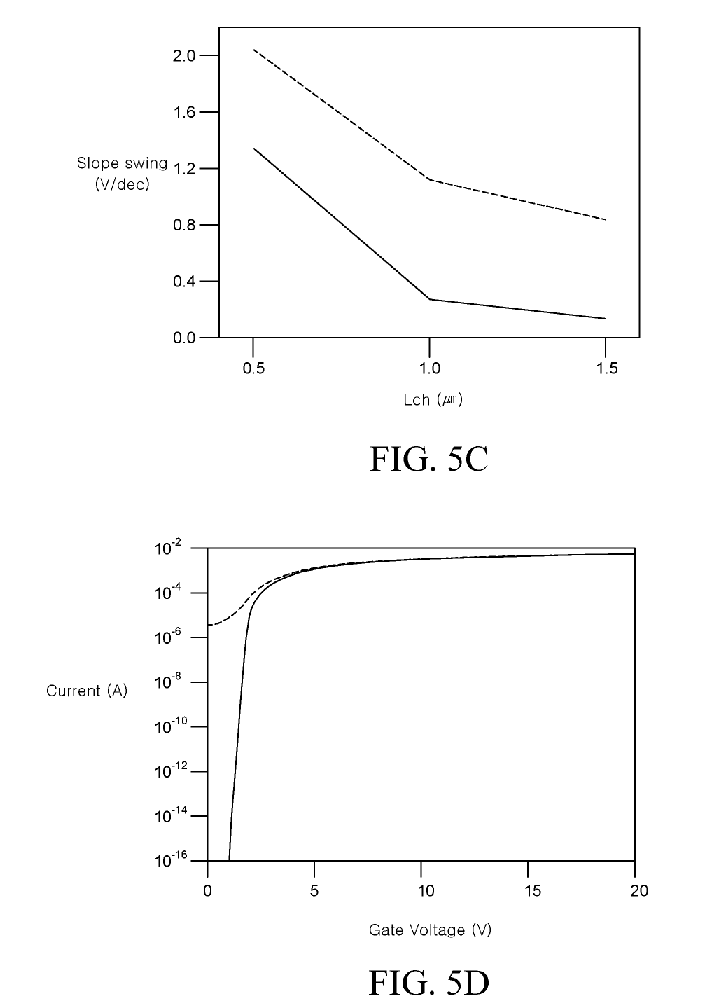

FIGS. 5A to 5D are simulation graphs illustrating a switching characteristic of a light emitting transistor according to another exemplary embodiment of the present disclosure. Hereinafter, a dotted line in FIGS. 5A to 5D refers to the exemplary embodiment without the channel auxiliary layer and a solid line in FIGS. 5A to 5D refers to another exemplary embodiment with the channel auxiliary layer.

Specifically, FIG. 5A is a graph illustrating a relationship of the on-current which flows in the channel area Ch when the transistor TR is turned on depending on the thickness Ti of the insulating layer 160, FIG. 5B is a graph illustrating the relationship of the leakage current which flows in the channel area Ch when the transistor TR is turned off depending on the thickness Ti of the insulating layer 160, FIG. 5C is a graph illustrating the relationship of voltage of the gate signal applied to the second electrode 172 and the current which flows in the channel area Ch, and FIG. 5D is a graph regarding the relationship of slope swing SS of the transistor TR depending on the length Lch of the channel area Ch.

In addition, the radius R of the luminescent area LA is 20 μm and the n-doping concentration of each of the first lower pattern 131 and the second lower pattern 132 is set to 10¹⁸ cm⁻³ and the thickness of each of the first lower pattern 131 and the second lower pattern 132 is set to 4 μm.

Referring to FIG. 5A, when the length Lch of the channel area Ch is set to 1.5 μm, the increase rate of the current when the thickness Ti of the insulating layer 160 is from 0.1 to 0.05 μm is relatively higher than the increase rate of the current when the thickness Ti of the insulating layer 160 is from 0.2 to 0.1 μm.

In addition, referring to FIG. 5B, when the length Lch of the channel area Ch is set to 1.5 μm, the decrease rate of the leakage current when the thickness Ti of the insulating layer 160 is from 0.1 to 0.05 μm is relatively lower than the decrease rate of the leakage current when the thickness Ti of the insulating layer 160 is from 0.2 to 0.1 μm.

Accordingly, referring to FIGS. 5A and 5B, when the thickness Ti of the insulating layer 160 is 0.1 μm or less, it can be seen that the switching characteristic of the transistor TR is enhanced. In addition, referring to FIGS. 5a and 5b, it can be seen that the switching characteristic of the light emitting transistor 400 according to another exemplary embodiment of the present disclosure is further enhanced than the switching characteristic of the light emitting transistor 100 according to the exemplary embodiment of the present disclosure.

And, referring to FIG. 5C, it can be seen that the slope swing SS value decreases when the length Lch of the channel area Ch is from 1 to 1.5 μm. Therefore, it can be seen that when the length Lch of the channel area Ch is 1 μm or more, the switching characteristic is enhanced. Further, the slope swing SS value is measured to be reduced as a whole in another exemplary embodiment as compared with the exemplary embodiment of the present disclosure. As a result, it can be seen that the switching characteristic of the light emitting transistor 400 according to another exemplary embodiment of the present disclosure is further enhanced than the switching characteristic of the light emitting transistor 100 according to the exemplary embodiment of the present disclosure.

And, referring to 5D, when the voltage of the gate signal is 20 V, the on-current which flows in the channel area Ch is measured at substantially the equivalent level in the exemplary embodiment and another exemplary embodiment of the present disclosure. However, when the voltage of the gate signal is 1.2 V, the leakage current which flows in the channel area Ch is approximately 10⁻⁵ A in the case of the exemplary embodiment of the present disclosure, but in the case of another exemplary embodiment of the present disclosure, the leakage current decreases to 10⁻¹² A to 10⁻¹⁴ A.

When the channel layer 120 is embodied using the undoped gallium nitride (u-GaN), a spontaneous-polarization phenomenon may occur in the channel layer 120 due to a crystallographic structure. Accordingly, referring to FIG. 2, in the region of the channel layer 120 overlapping with the second electrode 172, the spontaneous-polarization phenomenon may occur. As a result, the region of the channel layer 120 adjacent to the insulating layer 160 has a negative charge and the region of the channel layer 120 adjacent to the substrate 110 has a positive charge. Particularly, the channel area Ch of the channel layer 120 may include a front-channel adjacent to the insulating layer 160 and a back-channel adjacent to the substrate 110. In addition, the spontaneous-polarization phenomenon may occur causing the front-channel of the channel area Ch to have a negative charge and the back-channel of the channel area Ch to have a positive charge.

Therefore, whenanegative bias (i.e., a turn-off signal) is applied to the second electrode 172 of the transistor TR, the electrons gathered in the front-channel of the channel area Ch when the turn-on signal is applied are not scattered and some of the electrons may be gathered again in the back-channel of the channel area Ch having the positive charge. Accordingly, even though the turn-off signal is applied to the transistor TR, the current may continuously flow through the back-channel of the channel area Ch.

As illustrated in FIG. 4, a channel auxiliary layer 490 including a p-type semiconductor is formed below the channel layer 120 to suppress electrons from being gathered to the back-channel of the channel area Ch when the turn-off signal is applied.

Referring to FIGS. 5B and 5D, when the light emitting transistor 400 includes the channel auxiliary layer 490, it can be seen that the leakage current is rapidly reduced.

Consequently, the light emitting transistor 400 according to exemplary embodiment of the present disclosure including the channel auxiliary layer 490 has an enhanced switching characteristic of the light emitting transistor 400.

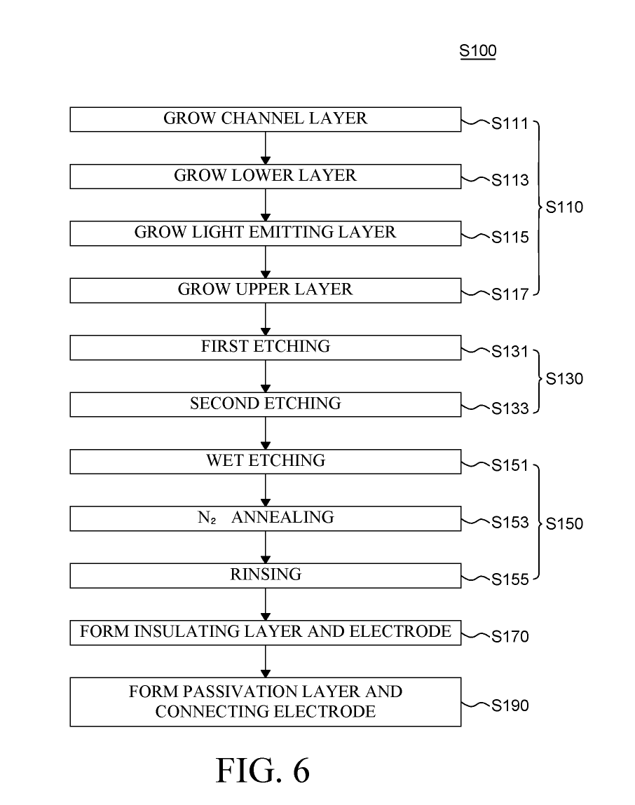

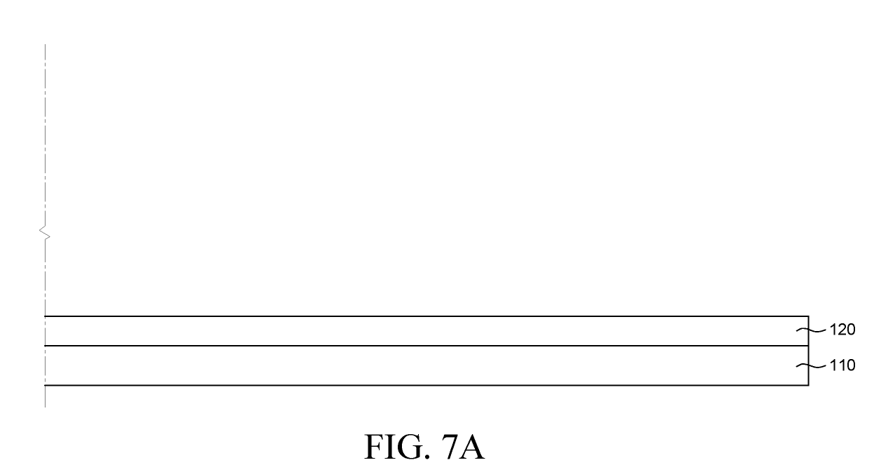

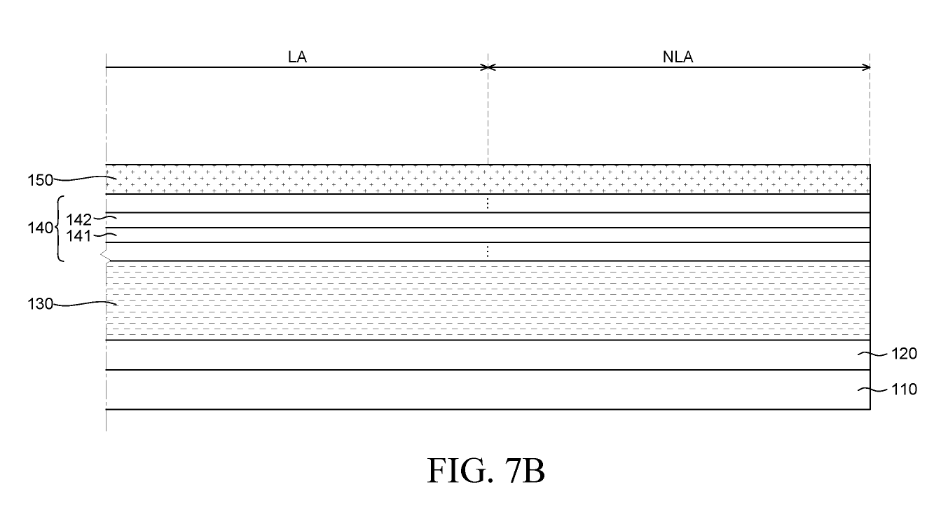

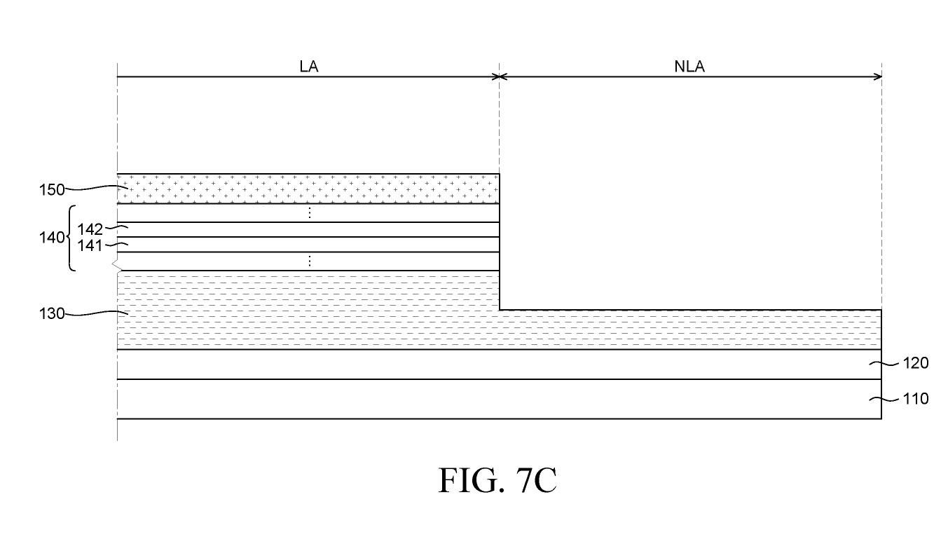

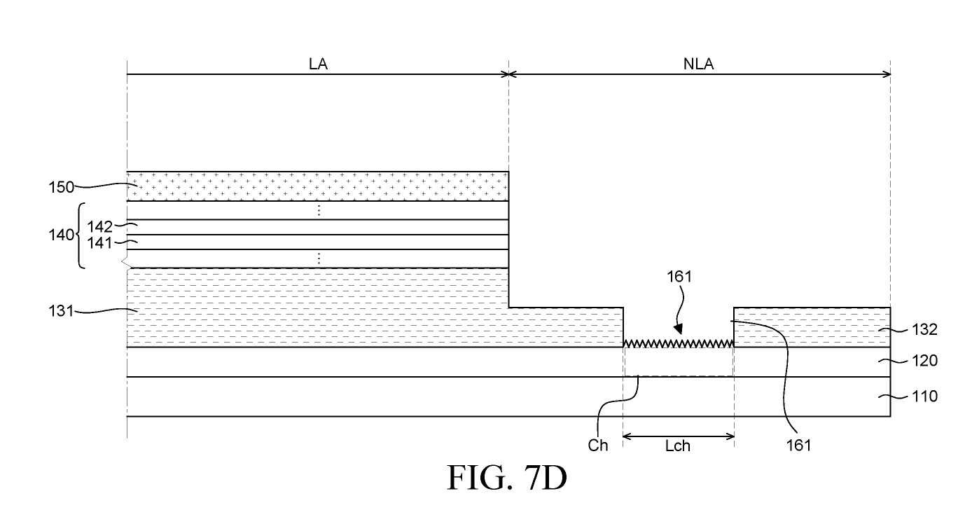

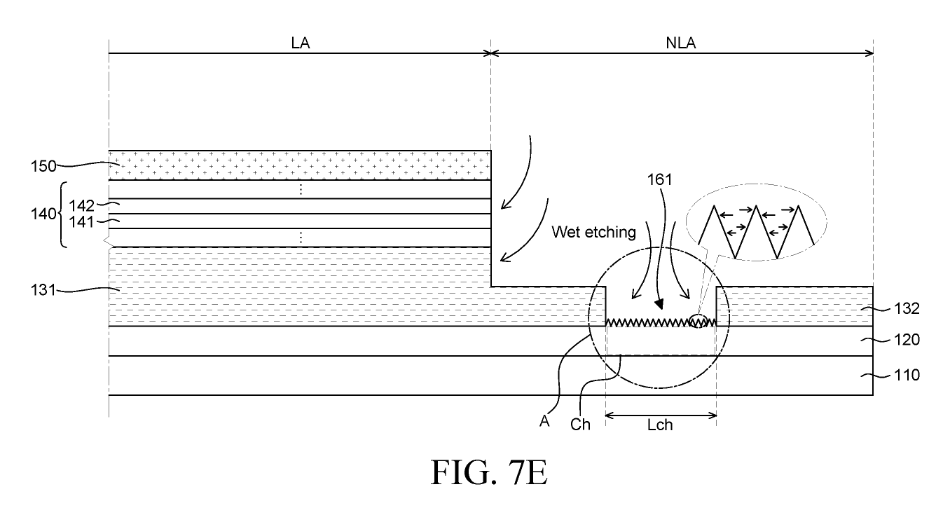

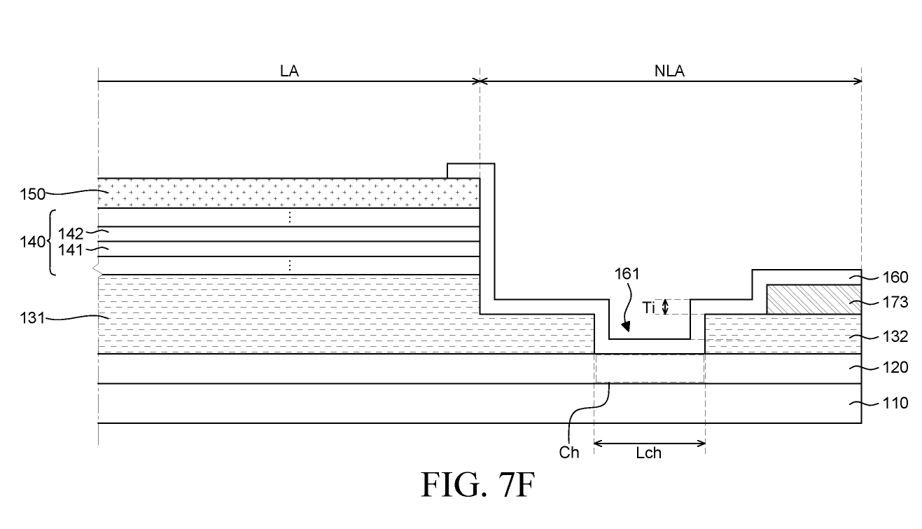

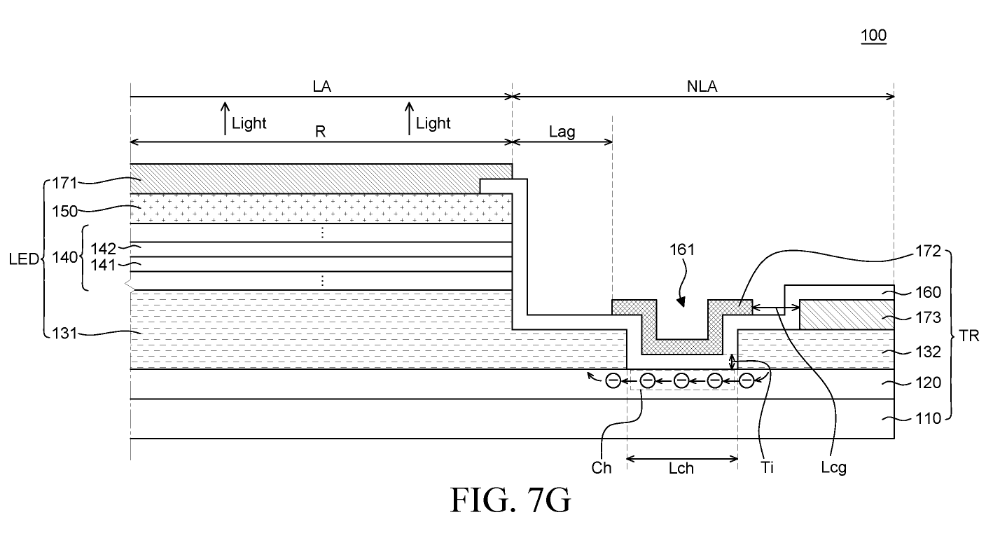

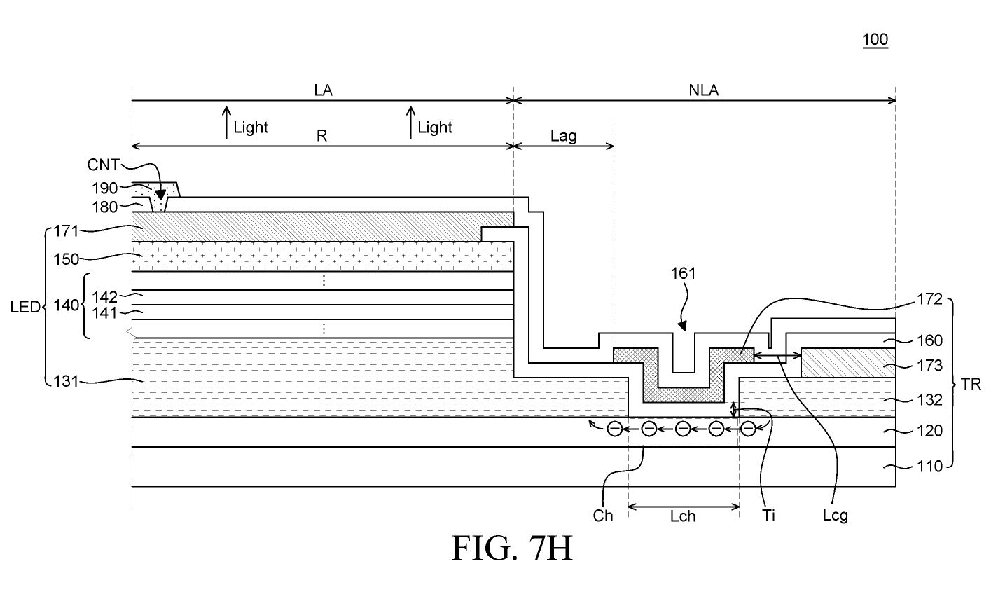

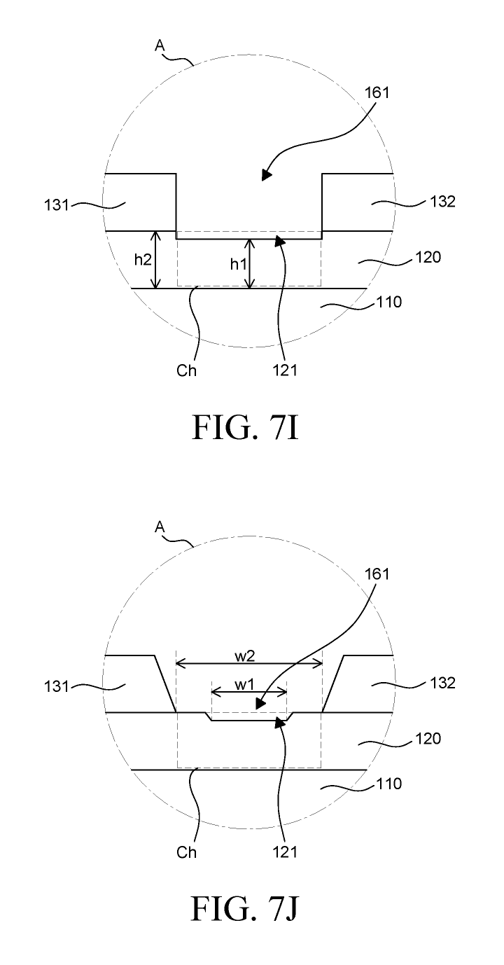

FIG. 6 is a flow chart illustrating a method for manufacturing a light emitting transistor according to an exemplary embodiment of the present disclosure. FIGS. 7A through 7H are process cross-sectional views illustrating the method of manufacturing the light emitting transistor according to the exemplary embodiment of the present disclosure. FIGS. 7I and 7J are an enlarged view of A in the FIG. 7E.

Referring to FIG. 6, a method (S100) of manufacturing a light emitting transistor according to an exemplary embodiment of the present disclosure includes a thin film growing step (S110), an etching step (S130), a surface treatment step (S150), an insulating layer and electrode forming step (S170), a passivation layer and connecting electrode forming step (S190).

First, the thin film growing step (S110) includes a channel layer growing step (S111), a lower layer growing step (S113), a light emitting layer growing step (S115), and an upper layer growing step (S117). Hereinafter, the method of growing the substrate 110 and the respective layers of the light emitting transistor 100 according to the exemplary embodiment of the present disclosure may be implemented by methods such as molecular beam epitaxy MBE, plasma enhanced chemical vapor deposition PECVD, vapor phase epitaxy VPE, as well as a general metal organic chemical vapor deposition MOCVD.

Referring to FIG. 7A, in the channel layer growing step (S111), a channel layer 120 is grown on the entire surface of the substrate 110.

Particularly, in the channel layer growing step (S111), un-doped GaN u-GaN may be grown on the substrate 110 with a thickness of 1 μm to 4 μm. Further, if necessary, for a switch characteristic of the light emitting transistor 100 according to the exemplary embodiment of the present disclosure, the channel layer 120 may be doped at a predetermined level.

In addition, in the channel layer growing step (S111), the channel layer 120 is grown under a condition of a high temperature and a high pressure toward the upper part of the channel layer 120, and then a gallium nitride u-GaN layer having high crystallinity is formed on the channel layer 120. As a result, crystallinity of a channel area Ch of a transistor TR may be enhanced. Accordingly, a current amount flowing through the channel area Ch is increased, thereby improving the switching characteristic of the light emitting transistor 100 according to the exemplary embodiment of the present disclosure.

The substrate 110 is to grow a gallium nitride GaN thin film as the channel layer 120, and as the substrate 110, an ideal gallium nitride GaN substrate 110 may be used for a nitride-based light emitting diode LED. However, there are disadvantages that it is difficult to manufacture a single-crystal substrate 110 using gallium nitride GaN and costs are high. Accordingly, the substrate 110 may be manufactured using sapphire, silicon Si, silicon carbide SiC, gallium arsenide GaAs, and zinc oxide ZnO, which are relatively easy to be obtained and have low unit cost.

Next, referring to FIG. 7B, in the lower layer growing step (S113), the lower layer 132 is grown on the entire surface of the channel layer 120.

More particularly, un-doped GaN u-GaN is grown on the channel layer 120 as a base layer of the lower layer 130 with a thickness of 2 μm to 4 μm, doped with an n-type impurity thereon to grow an n-type GaN n-GaN)layer.

Si may be used as the n-type impurity, and the gallium nitride u-GaN layer may be doped with the n-type impurity so that the n-doping concentration of the lower layer 130 is 10¹⁷ to 10¹⁸ cm⁻³.

Next, in the light emitting layer growing step (S140), the light emitting layer 140 is grown on the entire surface of the lower layer 130. That is, in order to enhance general quantum well QW or efficiency on the entire surface of the lower layer 130, a multiple quantum well structure MQW including a plurality of quantum well layers 141 and barrier layers 142 are grown to form the light emitting layer 140.

In order to grow the multiple quantum well structure MQW, gallium nitride u-GaN layers as the quantum well layers 141 and indium gallium nitride InGaN layers as the barrier layers 142 are alternately laminated.

For example, four or five pairs of quantum well layers 141 and barrier layers 142 are alternately laminated to grow the light emitting layer 140, and if necessary, the compositions and the thicknesses of the quantum well layer 141 and the barrier layer 142 may be adjusted.

Next, in the upper layer growing step (S117), the upper layer 150 is grown on the entire surface of the light emitting layer 140. Particularly, un-doped GaN u-GaN is grown on the light emitting layer 140 as a base layer of the upper layer 150 by a predetermined thickness, doped with a p-type impurity thereon to grow a p-type GaN p-GaN layer.

The p-type impurity may be one of Mg, Zn and Be.

The thin film growing step (S110) may be performed in the same reaction chamber. That is, the channel layer growing step (S111), the lower layer growing step (S113), the light emitting layer growing step (S115), and the upper layer growing step (S117) may be performed in the same chamber.

The thin film growing step (S110) for forming the transistor TR and the light emitting diode LED of the light emitting transistor 100 is performed in the same chamber, and thus, additional processes required for manufacturing the light emitting diode element and the transistor element as separate processes may not be added. Accordingly, the method (S100) of manufacturing the light emitting transistor according to the exemplary embodiment of the present disclosure is more simplified, thereby improving the process yield of the light emitting transistor 100.

Next, the etching step (S130) includes a first etching step (S131) for etching the upper layer 150, the light emitting layer 140 and a part of the lower layer 130 laminated in a non-luminescent area NLA and a second etching step (S133) of etching a part of the lower layer 130 laminated on the non-luminescent area NLA.

In the first etching step (S131), the upper layer 150 and the light emitting layer 140 laminated in the non-luminescent area NLA is etched to expose the lower layer 130 in the non-luminescent area NLA to the outside.

Alternatively, referring to FIG. 7C, in the first etching step (S131), the upper layer 150 and the light emitting layer 140 laminated in the non-luminescent area NLA are etched and may be over-etched by a thickness of the part of the lower layer 130 in the non-luminescent area NLA. In this case, the lower layer 130 may be etched stepwise. That is, the thickness of the lower layer 130 laminated on the non-luminescent area NLA may be smaller than the thickness of the lower layer 130 laminated on a luminescent area LA.

In addition, referring to FIG. 7D, in the second etching step (S133), the partial region of the lower layer 130 laminated on the non-luminescent area NLA is etched to form a trench 161 and expose the channel area Ch of the channel layer 120. That is, the upper surface of the channel area Ch is exposed through the second etching step (S133).

The width of the lower layer 130 to be etched may be 1 μm or more, which corresponds to a length Lch of the channel area Ch.

In addition, due to over-etching in the second etching step (S133), the partial area of the channel layer 120 may be etched. In this case, the length Lch of the channel area Ch of the transistor TR becomes longer to affect the switching characteristic of the transistor TR.

A first lower pattern 131 and a second lower pattern 132 may be formed to be spaced apart from each other by etching the lower layer 130 through the second etching step (S133). The first lower pattern 131 is laminated in the luminescent area LA and the second lower pattern 132 is laminated in the non-luminescent area NLA. However, if necessary, as illustrated in FIG. 7D, the first lower pattern 131 may be partially laminated even in the non-luminescent area NLA.

In the first etching step (S131) and the second etching step (S133), etching is performed using a photoresist mask. Although the first etching step (S131) and the second etching step (S133) are described separately for convenience of description, the first etching step (S131) and the second etching step (S133) may be performed by a single etching process using a photoresist mask having a plurality of thicknesses using a halftone photomask which is known in the related art.

In addition, in the first etching step (S131) and the second etching step (S133), since the etching is performed in a direction perpendicular to the substrate 110, anisotropic etching is performed and thus, the etching may be used for a dry etching method. Particularly, the first etching step (S131) and the second etching step (S133) maybe performed through an inductively coupled plasma ICP method with an improved etching rate.

In the inductively coupled plasma ICP method, chlorine-based gases such as Cl₂ and BCl₃ are used. As a result, the sides of the lower layer 130, the light emitting layer 140 and the upper layer 150 exposed in the first etching step (S131) are damaged, and thus, a current path that passes through the lower layer 130, the light emitting layer 140, and the upper layer 150 is generated. In addition, the roughness characteristic of the upper surface of the channel area Ch exposed in the second etching step (S133) is deteriorated, and thus, the switching characteristic of the transistor TR is also deteriorated. In order to solve the problem, surface treatment is required.

The surface treating step (S150) includes a wet etching step (S151), an N₂ annealing step (S153), and a rinsing step (S155).

First, referring to FIG. 7E, in the wet etching step (S151), the sides of the lower layer 130, the light emitting layer 140, and the upper layer 150 damaged in the first etching step (S131) are etched using a boiling etching solution, and in the second etching step (S133), the upper surface of the channel area Ch having a reduced roughness characteristic is etched.

Particularly, by using boiling KOH and NaOH, wet etching having a high etching rate in the horizontal direction may be performed. Accordingly, the damaged sides of the lower layer 130, the light emitting layer 140, and the upper layer 150 are etched, and the roughness characteristic may be improved by etching a horizontal component of the unevenness on the upper surface of the channel area Ch.

Due to the aforementioned wet etching step (S151), the current path passing through the lower layer 130, the light emitting layer 140 and the upper layer 150 is removed to increase the light emitting efficiency of the light emitting diode LED, improve the roughness characteristic of the upper surface of the channel area Ch, and increase the current amount flowing in the channel area Ch when the transistor TR is turned on.

In addition, the process of N₂ annealing the surface of the channel area Ch of the exposed channel layer 120 may be performed. Particularly, N₂, which is inert gas, is injected and heat-treated into the surface of the exposed channel area Ch, and thus ion damage caused by dry etching of the inductively coupled plasma ICP method performed in the etching step (S130) may be restored.

Next, in the rinsing step (S155), the surface of the channel area Ch etched in the wet etching step (S151) is rinsed with an acidic solution.

Particularly, the sides of the lower layer 130, the light emitting layer 140, and the upper layer 150 and the upper surface of the channel area Ch wet-etched are rinsed using an acidic solution such as nitric acid, chromic acid, phosphoric acid, chloric acid, sulfuric aqua regia. Thus, impurities on the upper surface of the channel area Ch are removed, thereby improving the surface characteristics of the channel area Ch. Accordingly, the switching characteristic of the transistor TR may be improved.

In the wet etching step (S151) for improving the roughness characteristic of the upper surface of the channel area Ch, a part of the upper surface of the channel area Ch may be removed.

In the wet etching step (S151), when the part of the upper surface of the channel area Ch is not removed, as illustrated in FIG. 7F, a portion where the insulating layer 160 contacts the channel area Ch of the channel layer 120 may be the upper surface of the channel area Ch. As illustrated in FIG. 71, when the part of the upper surface of the channel area Ch is removed from the channel layer 120 (e.g., when a concave portion 121 is formed in the channel area Ch of the channel layer 120), the insulating layer 160 may contact the side surface and the lower surface of the concave portion 121 formed in the channel area Ch.

As illustrated in FIG. 71, while performing the wet etching step (S151) for improving the roughness characteristic of the upper surface of the channel area Ch, a thickness h1 of the channel area Ch of the channel layer 120 may be smaller than a thickness h2 of the channel layer 120 disposed on the lower surface of the first lower pattern 131.

Numerical values such as the width and the depth of the concave portion 121 formed in the channel area Ch may be varied depending on the solution, an etching rate, an etching time, etc. of the wet etching process.

FIG. 71 illustrates that the width of the trench 161 and the width of the concave portion 121 coincide with each other, but the present invention is not limited thereto. According to the wet etching step (S151) having a high horizontal etching ratio, while the first lower pattern 131 and the second lower pattern 132 are etched in a horizontal direction, the width of the trench 161 may be larger than the width of the concave portion 121 formed in the channel area Ch. For example, as illustrated in FIG. 7J, a width w2 of the trench 161 may be larger than a width w1 of the concave portion 121 formed in the channel area Ch of the channel layer 120. Accordingly, the portion where the insulting layer 160 contacts the channel area Ch of the channel layer 120 may contact the upper surface of the channel area Ch and the side surface and the lower surface of the concave portion 121 formed in the channel area Ch.

When the concave portion 121 and the side surface of the trench 161 have a slope, a shortest distance among distances between the first lower pattern 131 and the second lower pattern 132 may be set as the width w2 of the trench 161. Further, the width of the lower surface of the concave portion 121 may be set as the width w1 of the concave portion 121.

Next, in the insulating layer and electrode forming step (S170), the insulating layer 160 is deposited to cover the exposed channel area Ch, and a first electrode 171, a second electrode 172, and a third electrode 173 are deposited.

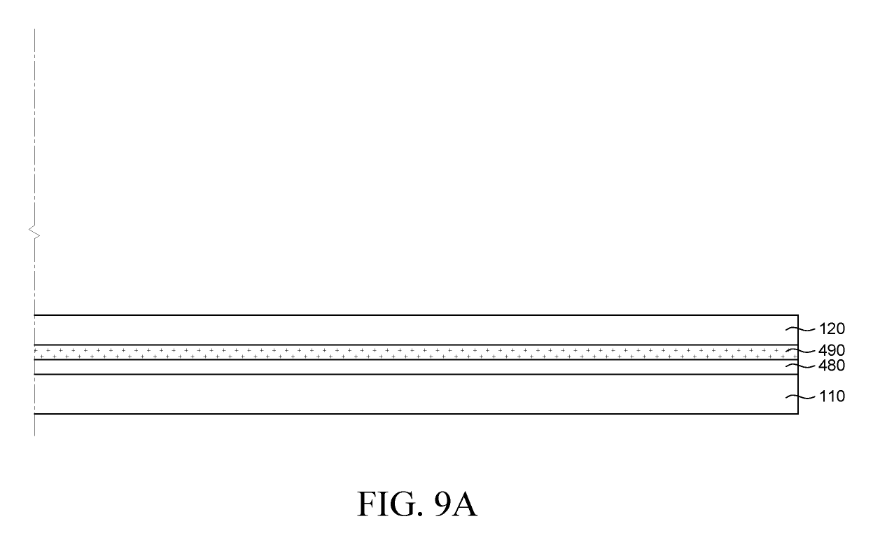

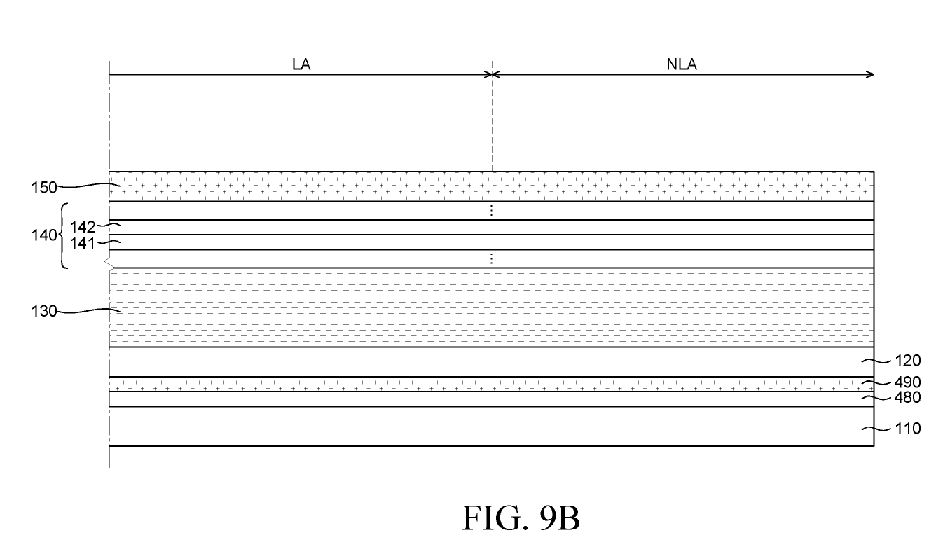

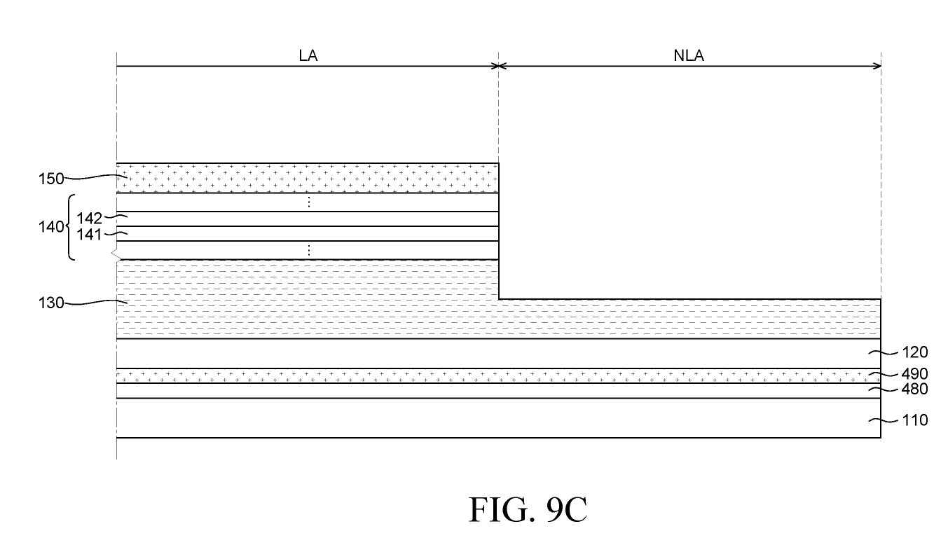

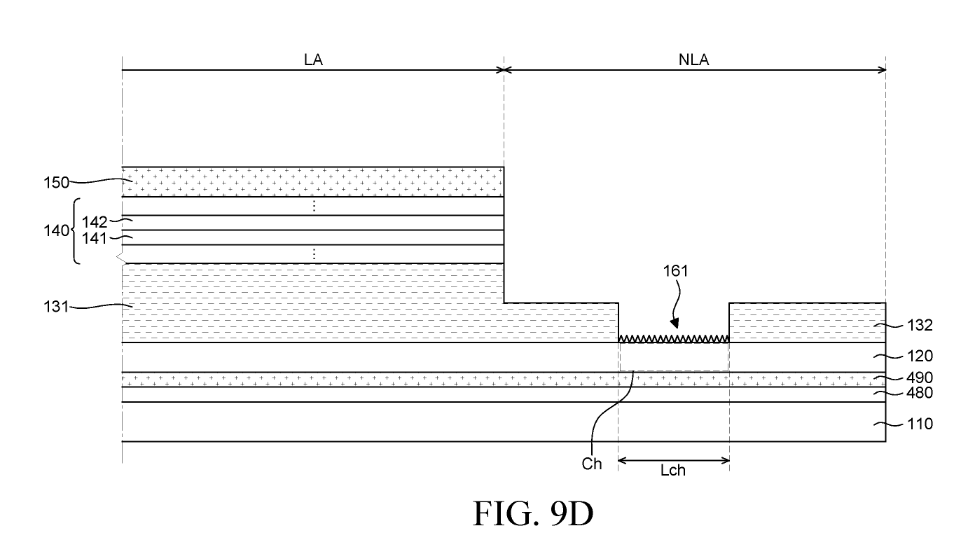

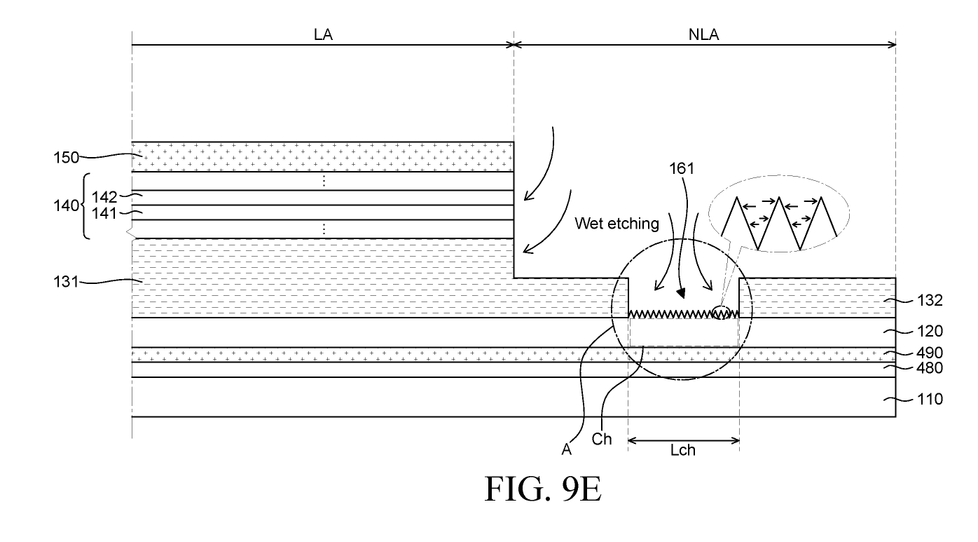

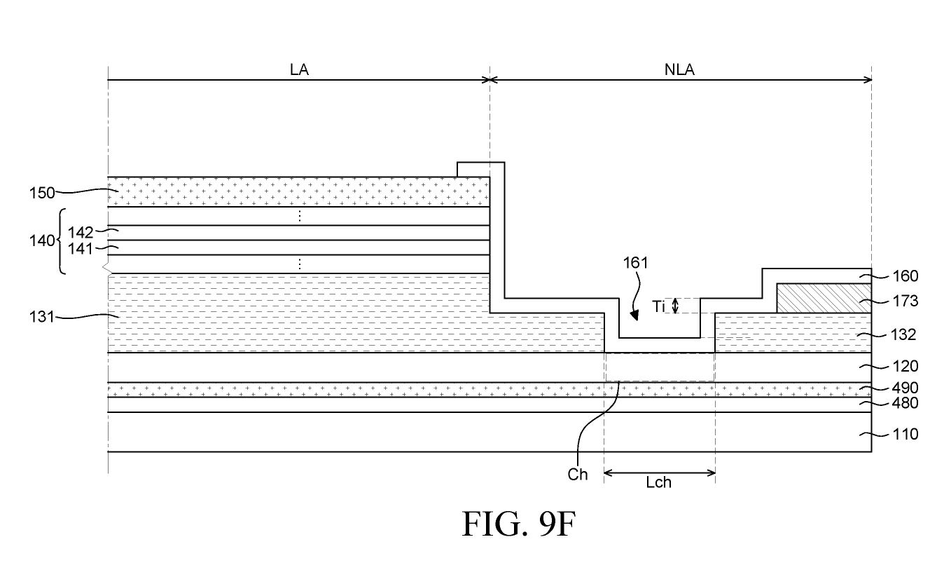

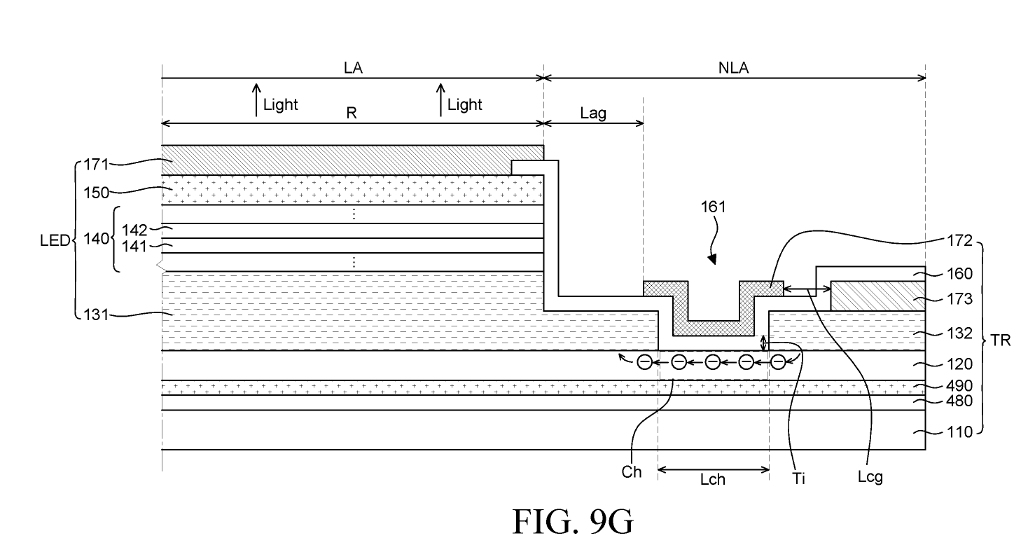

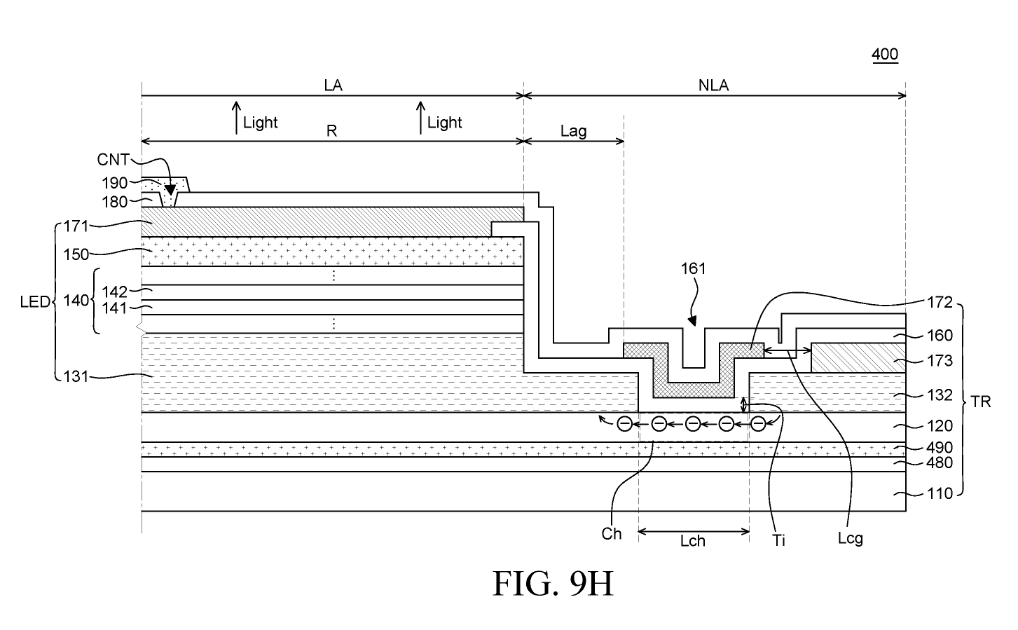

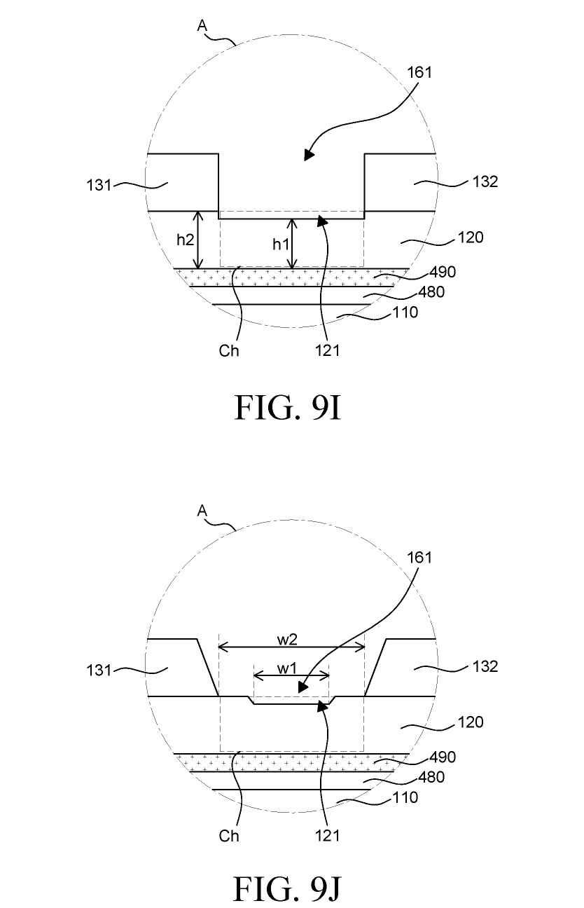

Referring to FIG. 7F, in the insulating layer and electrode forming step (S170), the third electrode 173 is deposited on the second lower pattern 132 in the non-luminescent area NLA, and the insulating layer 160 is deposited to cover the channel layer 120 exposed between the first lower pattern 131 and the second lower pattern 132 in the non-luminescent area NLA. And, the insulating layer 160 may be deposited to cover the third electrode 173. The insulating layer 160 is deposited to cover the upper surface of the channel area Ch and the third electrode 173. The insulating layer 160 also extends on the second lower pattern 132 and the side surfaces of the first lower pattern 131, the light emtting layer 140, and the upper layer 150, as illustrated in FIG. 9F.

In addition, in order to improve the switching characteristic of the transistor TR, a thickness Ti of the insulating layer 160 may be deposited within 0.1 μm.

The third electrode 173 may be formed by depositing other conductive metal materials such as silver Ag, an Ag alloy, copper Cu, a copper alloy, aluminum Al, an aluminum alloy, silver Ag, titanium Ti, titanium alloy, molybdenum Mo, molybdenum alloy, and aluminum-neodymium by a sputtering method.

The insulating layer 160 may be formed of an inorganic insulating material or an organic insulating material, and the inorganic insulating material maybe one of Al₂O₃, ZrO₂, HfO₂, TiO₂, ZnO, Y₂O₃, CeO₂, Ta₂O₅, La₂O₅, Nb₂O₅, SiO₂, SiNx, and AlN and the organic insulating material maybe one of benzocyclobutene BCB and acrylic resins.

The method of depositing the insulating layer 160 described above may use various deposition methods such as physics vapor deposition PVD and chemical vapor deposition CVD, but it is preferable to use a plasma enhanced chemical vapor deposition PECVD deposition method.

Next, referring to FIG. 7G, in the insulating layer and electrode forming step (S170), the first electrode 171 is deposited on the upper layer 150 of the luminescent area LA, the second electrode 172 is deposited on the insulating layer 160 disposed in the non-luminescent area NLA.

The second electrode 172 may be formed by depositing other conductive metal materials such as silver Ag, an Ag alloy, copper Cu, a copper alloy, aluminum Al, an aluminum alloy, silver Ag, titanium Ti, titanium alloy, molybdenum Mo, molybdenum alloy, and aluminum-neodymium by a sputtering method, and since the first electrode 171 is disposed in the luminescent area LA, the first electrode 171 may be formed by depositing a transparent electrode material such as indium tin oxide ITO, which may transmit light generated in the light emitting layer 140 by a sputtering method.

In addition, the transparent electrode material is deposited so that a spacing distance Lag in a horizontal direction between the first electrode 171 and the second electrode 172 and a spacing distance Lcg between the second electrode 172 and the third electrode 173 may be 2 μm or more, respectively. As such, by setting the spacing distance between the first electrode 171, the second electrode 172 and the third electrode 173, interference of signals applied to the electrodes 171, 172, and 173 may be reduced.

Next, referring to FIG. 7H, in the passivation layer and connecting electrode forming step (S190), the passivation layer 180 is deposited on the first electrode 171, the insulating layer 160, and the second electrode 172. The passivation layer is formed in the entirety of the luminescent area LA and the non-luminescent area NLA.

And, in the luminescent area LA, the contact hole CNT maybe formed through the passivation layer 180 to expose the first electrode 171 through the contact hole CNT.

The connecting electrode 190 may be formed on the passivation layer 180 in the luminescent area LA. And, The connecting electrode 190 may be in connection with the first electrode 171 through the contact hole CNT of the passivation layer 180. The connecting electrode 190 may be formed as a same material with at least one of the first electrod 171, the second electrode 172, and the third electrode 173.

As such, the thin film growing step (S110) for forming the transistor TR and the light emitting diode LED of the light emitting transistor 100 is performed in the same semiconductor fabrication chamber, and thus, obviates separate processes for for manufacturing the light emitting diode element and the transistor element. Accordingly, the method (S100) of manufacturing the light emitting transistor according to the exemplary embodiment of the present disclosure is more simplified, thereby improving the process yield of the light emitting transistor 100.

Further, according to the method (S100) of manufacturing the light emitting transistor according to the exemplary embodiment of the present disclosure, the light emitting diode LED and the transistor TR may be manufactured on one substrate 110 through the same manufacturing process. Thus, the overall combined size of the light emitting diode LED and the transistor TR may be reduced, and thus, enabling more compact micro displays.

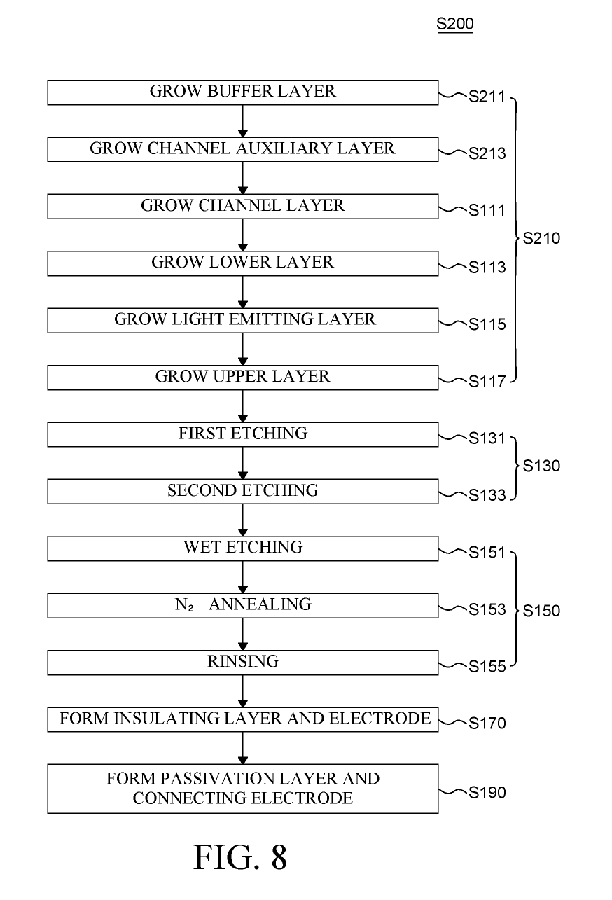

Hereinafter, a method (S200) of manufacturing a light emitting transistor according to another exemplary embodiment of the present disclosure will be described with reference to FIG. 8. FIG. 8 is a flow chart illustrating a method for manufacturing a light emitting transistor according to another exemplary embodiment of the present disclosure. FIGS. 9A through 9H are process cross-sectional views illustrating the method of manufacturing the light emitting transistor according to another exemplary embodiment of the present disclosure. FIGS. 91 and9J are an enlarged view of A in the FIG. 9E.

Referring to FIG. 8, a method (S200) of manufacturing a light emitting transistor according to the exemplary embodiment of the present disclosure includes a thin film growing step (S210), an etching step (S130), a surface treating step (S150), an insulating layer and electrode forming step (S170), and a passivation layer and connecting electrode forming step (S190).

The thin film growing step (S210) includes a buffer layer growing step (S211), a channel auxiliary layer growing step (S213), a channel layer growing step (S111), a lower layer growing step (S113), a light emitting layer growing step (S115), and an upper layer growing step (S117).

That is, when the method (S200) for manufacturing the light emitting transistor according to another exemplary embodiment of the present disclosure is compared with the method (S100) for manufacturing the light emitting transistor according to an exemplary embodiment of the present disclosure, the method (S200) further includes a buffer layer growing step (S211) and a channel auxiliary layer growing step (S213) before the channel layer growing step (S111).

Referring to FIG. 9A, in the buffer layer growing step (S211), a buffer layer 480 is grown on the entire surface of the substrate 110. Particularly, in the buffer layer growing step (S211), un-doped GaN u-GaN may be grown on the substrate 110 with a predetermined thickness. Further, if necessary, for the characteristic of a light emitting transistor 400 according to another exemplary embodiment of the present disclosure, the buffer layer 480 may be p-doped at a concentration lower than a p-doping concentration of a channel auxiliary layer 490.

In addition, in the buffer layer growing step (S211), the buffer layer 480 is grown under a high temperature and high pressure condition toward the upper part of the buffer layer 480, and then a gallium nitride u-GaN layer having high crystallinity may be grown on the buffer layer 480.

Next, in the channel auxiliary layer growing step (S213), a channel auxiliary layer 490 is grown on the entire surface of the buffer layer 480. Particularly, un-doped GaN u-GaN is grown on the buffer layer 480 as a base layer of the channel auxiliary layer 490 by a thickness of about 1 μm and doped with a p-type impurity thereon to grow a p-type GaN p-GaN layer.

The p-type impurity may be any one of Mg, Zn, and Be, and the u-GaN layer may be doped with the p-type impurity so that the p-doping concentration of the channel auxiliary layer 490 is 10 ¹⁹ to 10²⁰ cm⁻³.

As such, by growing the channel auxiliary layer 490 in the channel auxiliary layer growing step (S213), the residual of the channel area Ch caused by a self-polarization phenomenon of gallium nitride GaN is suppressed to reduce a leakage current.

The method (S200) of manufacturing the light emitting transistor according to another exemplary embodiment of the present disclosure is the same as the method (S100) of manufacturing the light emitting transistor according to an exemplary embodiment of the present disclosure.

Next, in the channel layer growing step (S111), the channel layer 120 is grown on the entire surface of the channel auxiliary layer 490. Particularly, in the channel layer growing step (S111), un-doped GaN u-GaN may be grown on the channel auxiliary layer 490 with a thickness of 1 μm to 4 μm. Further, if necessary, for a switching characteristic of the light emitting transistor 400 according to the exemplary embodiment of the present disclosure, the channel layer 120 may be doped at a predetermined level.

In addition, in the channel layer growing step (S111), the channel layer 120 is grown under the high temperature and high pressure condition toward the upper part of the channel layer 120, and then a gallium nitride u-GaN layer having high crystallinity is formed on the channel layer 120. As a result, crystallinity of a channel area Ch of a transistor TR may be enhanced. Accordingly, a current amount flowing through the channel area Ch is increased, thereby improving the switching characteristic of the light emitting transistor 400 according to the exemplary embodiment of the present disclosure.

Next, referring to FIG. 9B, in the lower layer growing step (S113), the lower layer 132 is grown on the entire surface of the channel layer 120.

More particularly, un-doped GaN u-GaN is grown on the channel layer 120 as a base layer of the lower layer 130 with a thickness of 2 μm to 4 μm and doped with an n-type impurity thereon to grow an n-type GaN n-GaN layer.

Si may be used as the n-type impurity, and the gallium nitride u-GaN layer may be doped with the n-type impurity so that the n-doping concentration of the lower layer 130 is 10¹⁷ to 10¹⁸ cm⁻³.

Next, in the light emitting layer growing step (S140), the light emitting layer 140 is grown on the entire surface of the lower layer 130.

That is, in order to enhance general quantum well QW or efficiency on the entire surface of the lower layer 130, multiple quantum wells MQW including a plurality of quantum well layers 141 and barrier layers 142 are grown to form the light emitting layer 140.

In order to grow the multiple quantum well structure MQW, gallium nitride u-GaN layers as the quantum well layers 141 and indium gallium nitride InGaN layers as the barrier layers 142 are alternately laminated.

For example, four or five pairs of quantum well layers 141 and barrier layers 142 are alternately laminated to grow the light emitting layer 140, and if necessary, the compositions and the thicknesses of the quantum well layer 141 and the barrier layer 142 may be adjusted.

Next, in the upper layer growing step (S117), the upper layer 150 is grown on the entire surface of the light emitting layer 140. Particularly, un-doped GaN u-GaN is grown on the light emitting layer 140 as a base layer of the upper layer 150 by a predetermined thickness, doped with a p-type impurity thereon to grow a p-type GaN p-GaN layer.

The p-type impurity may be any one of Mg, Zn and Be.

The thin film growing step (S210) of the method (S200) for manufacturing the light emitting transistor according to another exemplary embodiment of the present disclosure may be performed in the same reaction chamber. That is, the buffer layer growing step (S211), the channel auxiliary growing step (S213), the channel layer growing step (S111), the lower layer growing step (S113), the light emitting layer growing step (S115), and the upper layer growing step (S117) may be performed in the same chamber.

Next, the etching step (S130) includes a first etching step (S131) for etching the upper layer 150, the light emitting layer 140 and a part of the lower layer 130 laminated in a non-luminescent area NLA and a second etching step (S133) of etching a partial area of the lower layer 130 laminated on the non-luminescent area NLA.

In the first etching step (S131), the upper layer 150 and the light emitting layer 140 laminated on the non-luminescent area NLA are etched to expose the lower layer 130 in the non-luminescent area NLA to the outside.

Alternatively, referring to FIG. 9C, in the first etching step (S131), the upper layer 150 and the light emitting layer 140 laminated in the non-luminescent area NLA are etched and over-etched by the thickness of the part of the lower layer 130 in the non-luminescent area NLA. In this case, the lower layer 130 may be etched stepwise. That is, the thickness of the lower layer 130 laminated on the non-luminescent area NLA may be smaller than the thickness of the lower layer 130 laminated on a luminescent area LA.

In addition, referring to FIG. 9D, in the second etching step (S133), the partial region of the lower layer 130 laminated on the non-luminescent area NLA is etched to form a trench 161 and expose the channel area Ch of the channel layer 120. That is, the upper surface of the channel area Ch is exposed through the second etching step (S133).

The width of the lower layer 130 to be etched may be 1 μm or more, which corresponds to a length Lch of the channel area Ch.

In addition, due to over-etching in the second etching step (S133), the partial area of the channel layer 120 may be etched. In this case, the length Lch of the channel area Ch of the transistor TR becomes longer to affect the switching characteristic of the transistor TR.

A first lower pattern 131 and a second lower pattern 132 may be formed to be spaced apart from each other by etching the lower layer 130 through the second etching step (S133). The first lower pattern 131 is laminated in the luminescent area LA and the second lower pattern 132 is laminated in the non-luminescent area NLA. However, if necessary, as illustrated in FIG. 9D, the first lower pattern 131 may be partially laminated even in the non-luminescent area NLA.

In the first etching step (S131) and the second etching step (S133), etching is performed using a photoresist mask. Although the first etching step (S131) and the second etching step (S133) are described separately for convenience of description, the first etching step (S131) and the second etching step (S133) may be performed by a single etching process using a photoresist mask having a plurality of thicknesses using a halftone photomask which is known in the related art.

In addition, in the first etching step (S131) and the second etching step (S133), since the etching is performed in a direction perpendicular to the substrate 110, anisotropic etching is performed and thus, the etching may be used for a dry etching method. Particularly, the first etching step (S131) and the second etching step (S133) may be performed through an inductively coupled plasma ICP method with an enhanced etching rate.

In the inductively coupled plasma ICP method, chlorine-based gases such as Cl₂ and BCl₃ are used. As a result, the sides of the lower layer 130, the light emitting layer 140 and the upper layer 150 exposed in the first etching step (S131) are damaged, and thus, a current path that passes through the lower layer 130, the light emitting layer 140, and the upper layer 150 is generated. In addition, the roughness characteristic of the upper surface of the channel area Ch exposed in the second etching step (S133) is deteriorated, and thus, the switching characteristic of the transistor TR is also deteriorated. In order to solve the problem, surface treatment is required.

The surface treating step (S150) includes a wet etching step (S151), an N₂ annealing step (S153), and a rinsing step (S155).

First, referring to FIG. 9E, in the wet etching step (S151), the sides of the lower layer 130, the light emitting layer 140, and the upper layer 150 damaged in the first etching step (S131) are etched using a boiling etching solution, and in the second etching step (S133), the upper surface of the channel area Ch having a reduced roughness characteristic is etched.

Particularly, by using boiling KOH and NaOH, wet etching having a high etching rate in the horizontal direction may be performed. Accordingly, the damaged sides of the lower layer 130, the light emitting layer 140, and the upper layer 150 are etched, and the roughness characteristic may be improved by etching a horizontal component of the unevenness on the upper surface of the channel area Ch.

Due to the aforementioned wet etching step (S151), the current path passing through the lower layer 130, the light emitting layer 140 and the upper layer 150 is removed to increase the light emitting efficiency of the light emitting diode LED, improve the roughness characteristic of the upper surface of the channel area Ch, and increasing the current amount flowing in the channel area Ch when the transistor TR is turned on.

In addition, the process of N₂ annealing the surface of the channel area Ch of the exposed channel layer 120 may be performed.

Particularly, N₂, which is inert gas, is injected and heat-treated into the surface of the exposed channel area Ch, and thus, the ion damage caused by dry etching of the inductively coupled plasma ICP method performed in the etching step (S130) may be restored.

Next, in the rinsing step (S155), the surface of the channel area Ch etched in the wet etching step (S151) is rinsed with an acidic solution.

Particularly, the sides of the lower layer 130, the light emitting layer 140, and the upper layer 150 and the upper surface of the channel area Ch wet-etched are rinsed using an acidic solution such as nitric acid, chromic acid, phosphoric acid, chloric acid, sulfuric aqua regia. Thus, impurities on the upper surface of the channel area Ch are removed, thereby improving the surface characteristics of the channel area Ch. Accordingly, the switching characteristic of the transistor TR may be improved.

In the wet etching step (S151) for improving the roughness characteristic of the upper surface of the channel area Ch, a part of the upper surface of the channel area Ch may be removed.

In the wet etching step (S151), when the part of the upper surface of the channel area Ch is not removed, as illustrated in FIG. 9F, a portion where the insulating layer 160 contacts the channel area Ch of the channel layer 120 may be the upper surface of the channel area Ch. As illustrated in FIG. 91, when the part of the upper surface of the channel area Ch is removed from the channel layer 120 (e.g., when a concave portion 121 is formed in the channel area Ch of the channel layer 120), the insulating layer 160 may contact the side surface and the lower surface of the concave portion 121 formed in the channel area Ch. As illustrated in FIG. 91, while performing the wet etching step (S151) for improving the roughness characteristic of the upper surface of the channel area Ch, a thickness h1 of the channel area Ch of the channel layer 120 may become thinner than a thickness h2 of the channel layer 120 disposed on the lower surface of the first lower pattern 131.

Numerical values such as the width and the depth of the concave portion 121 formed in the channel area Ch may be varied depending on the solution, an etching rate, an etching time, etc. of the wet etching process.

FIG. 9I illustrates the width of the trench 161 and the width of the concave portion 121 coinciding with each other, but the present invention is not limited thereto. According to the wet etching step (S151) having a high horizontal etching ratio, while the first lower pattern 131 and the second lower pattern 132 are etched in a horizontal direction, the width of the trench 161 may be larger than the width of the concave portion 121 formed in the channel area Ch. For example, as illustrated in FIG. 9J, a width w2 of the trench 161 may be larger than a width wl of the concave portion 121 formed in the channel area Ch of the channel layer 120. Accordingly, the portion where the insulting layer 160 contacts the channel area Ch of the channel layer 120 may contact the upper surface of the channel area Ch and the side surface and the lower surface of the concave portion 121 formed in the channel area Ch.

When the concave portion 121 and the side surface of the trench 161 have a slope, a shortest distance among distances between the first lower pattern 131 and the second lower pattern 132 maybe set as the width w2 of the trench 161. Further, the width of the lower surface of the concave portion 121 may be set as the width wl of the concave portion 121.

Next, in the insulating layer and electrode forming step (S170), the insulating layer 160 is deposited to cover the exposed channel area Ch, and a first electrode 171, a second electrode 172, and a third electrode 173 are deposited.

Referring to FIG. 9F, in the insulating layer and electrode forming step (S170), the third electrode 173 is deposited on the second lower pattern 132 in the non-luminescent area NLA, and the insulating layer 160 is deposited to cover the channel layer 120 exposed between the first lower pattern 131 and the second lower pattern 132 in the non-luminescent area NLA. And, the insulating layer 160 may be deposited to cover the third electrode 173. The insulating layer 160 is deposited to cover the upper surface of the channel area Ch and the third electrode 173. The insulating layer 160 also extends on the second lower pattern 132 and the side surfaces of the first lower pattern 131, the light emtting layer 140, and the upper layer 150, as illustrated in FIG. 9F.

In addition, in order to improve the switching characteristic of the transistor TR, a thickness Ti of the insulating layer 160 may be deposited within 0.1 μm.

The third electrode 173 may be formed by depositing other conductive metal materials such as silver Ag, an Ag alloy, copper Cu, a copper alloy, aluminum Al, an aluminum alloy, silver Ag, titanium Ti, titanium alloy, molybdenum Mo, molybdenum alloy, and aluminum-neodymium by a sputtering method.

The insulating layer 160 may be formed of an inorganic insulating material or an organic insulating material, and the inorganic insulating material maybe one of Al₂O₃, ZrO₂, HfO₂, TiO₂, ZnO, Y₂O₃, CeO₂, Ta₂O₅, La₂O₅, Nb₂O₅, SiO₂, SiNx, and AlN and the organic insulating material maybe one of benzocyclobutene BCB and acrylic resins.

The method of depositing the insulating layer 160 described above may use various deposition methods such as physics vapor deposition PVD and chemical vapor deposition CVD, but it is preferable to use a plasma enhanced chemical vapor deposition PECVD method.

Next, referring to FIG. 9G, in the insulating layer and electrode forming step (S170), the first electrode 171 is deposited on the upper layer 150 in the luminescent area LA, the second electrode 172 is deposited on the insulating layer 160 disposed in the non-luminescent area NLA. The second electrode 172 may be formed by depositing other conductive metal materials such as silver Ag, an Ag alloy, copper Cu, a copper alloy, aluminum Al, an aluminum alloy, silver Ag, titanium Ti, titanium alloy, molybdenum Mo, molybdenum alloy, and aluminum-neodymium by a sputtering method, and since the first electrode 171 is disposed in the luminescent area LA, the first electrode 171 may be formed by depositing a transparent electrode material such as indium tin oxide ITO, which may transmit light generated in the light emitting layer 140 by a sputtering method.

In addition, the transparent electrode material is deposited so that a spacing distance Lag in a horizontal direction between the first electrode 171 and the second electrode 172 and a spacing distance Lcg between the second electrode 172 and the third electrode 173 may be 2 μm or more, respectively. As such, by setting the spacing distance between the first electrode 171, the second electrode 172 and the third electrode 173, interference of signals applied to the electrodes 171, 172, and 173 may be reduced.

Next, referring to FIG. 9H, in the passivation layer and connecting electrode forming step (S190), the passivation layer 180 is deposited on the first electrode 171, the insulating layer 160, and the second electrode 172. The passivation layer is formed in the entirety of the luminescent area LA and the non-luminescent area NLA.

And, in the luminescent area LA, the contact hole CNT maybe formed through the passivation layer 180 to expose the first electrode 171 through the contact hole CNT.

The connecting electrode 190 may be formed on the passivation layer 180 in the luminescent area LA. And, The connecting electrode 190 may be in connection with the first electrode 171 through the contact hole CNT of the passivation layer 180. The connecting electrode 190 may be formed as a same material with at least one of the first electrod 171, the second electrode 172, and the third electrode 173.

The thin film growing step (S210) for forming the transistor TR and the light emitting diode LED of the light emitting transistor 400 is performed in the same semiconductor fabrication chamber, and thus, obviates separate processes for manufacturing the light emitting diode element and the transistor element. Accordingly, the method (S200) of manufacturing the light emitting transistor according to another exemplary embodiment of the present disclosure is more simplified, thereby improving the process yield of the light emitting transistor 400.

Further, in the method (S200) of manufacturing the light emitting transistor according to another exemplary embodiment of the present disclosure, the buffer layer 480 and the channel auxiliary layer 490 are additionally grown through the buffer layer growing step (S211) and the channel auxiliary layer growing step (S213), thereby reducing a leakage current flowing in the channel area Ch when the transistor TR is turned on.

The exemplary embodiments of the present disclosure can also be described as follows:

According to an aspect of the present disclosure, a light emitting transistor includes: a channel layer disposed on a substrate; a lower layer including a first lower pattern disposed in the luminescent area and a second lower pattern disposed to be spaced apart from the first lower pattern in the non-luminescent area, which are disposed on the channel layer; a light emitting layer disposed on the first lower pattern; an upper layer disposed on the light emitting layer; a first electrode disposed on the upper layer; an insulating layer disposed between the first lower pattern and the second lower pattern in the non-luminescent area; a second electrode disposed on the insulating layer; and a third electrode disposed on the second lower pattern.

According to another aspect of the present disclosure, the channel layer maybe an intrinsic semiconductor layer, the first lower pattern and second lower pattern maybe n-type semiconductor layer, the light emitting layer may be a multiple quantum well layer, and the upper layer may be a p-type semiconductor layer.

According to yet another aspect of the present disclosure, a dimension of the luminescent area may be 65% or more of the sum of the dimension of the luminescent area and a dimension of the non-luminescent area.

According to still yet another aspect of the present disclosure, a length up to an outermost portion from the center of the luminescent area may be within 30 μm.

According to still yet another aspect of the present disclosure, a thickness of the insulating layer may be within 0.1 μm.

According to still yet another aspect of the present disclosure, a distance between the first lower pattern and the second lower pattern may be 1 μm or more.

According to still yet another aspect of the present disclosure, the thickness of the channel layer may be 1 to 4 μm.

According to still yet another aspect of the present disclosure, the light emitting transistor may further include a current spreading layer disposed between the first lower pattern and the channel layer.

According to still yet another aspect of the present disclosure, a channel auxiliary layer may be disposed between the substrate and the channel layer and the channel auxiliary layer may be the p-type semiconductor layer.

According to still yet another aspect of the present disclosure, a p-doping concentration of the channel auxiliary layer may be 10¹⁹ to 10²⁰ cm⁻³.

According to still yet another aspect of the present disclosure, a buffer layer may be disposed between the channel auxiliary layer and the substrate and the p-doping concentration of the buffer layer may be lower than the p-doping concentration of the channel auxiliary layer.

According to another aspect of the present disclosure, a light emitting transistor includes: a light emitting diode disposed in a luminescent area; and a transistor disposed in a non-luminescent area, and the light emitting diode includes a light emitting layer and a first lower pattern disposed below the light emitting layer, and the transistor includes a channel layer, the first lower pattern on the channel layer, a second lower pattern disposed to be spaced apart from the first lower pattern in the same layer, an insulating layer on the channel layer, and a second electrode disposed on the insulating layer.

According to another aspect of the present disclosure, the first lower pattern may serve as both one terminal of the transistor and one terminal of the light emitting diode.

According to yet another aspect of the present disclosure, a method for manufacturing a light emitting transistor includes: growing a channel layer on a substrate in which a luminescent area and a non-luminescent area are defined; growing a lower layer on the channel layer; growing a light emitting layer on the lower layer; growing an upper layer on the light emitting layer; etching the upper layer and the light emitting layer stacked in the non-luminescent area; exposing a channel area of the channel layer by etching a partial area of the lower layer stacked in the non-luminescent area; forming an insulating layer so as to cover the exposed channel area; and forming a first electrode on the upper layer, forming a second electrode on the insulating layer, and forming a third electrode on the lower layer which remains in the non-luminescent area to perform thin-film growth in the same reaction chamber, thereby enhancing a process yield of the light emitting transistor.

According to another aspect of the present disclosure, the method may further include, before the growing of the channel layer, growing a channel auxiliary layer which is a p-type semiconductor layer of 10¹⁹ to 10²⁰ cm⁻³ on the substrate.

According to yet another aspect of the present disclosure, the method may further include, before the growing of the channel auxiliary layer, growing the buffer layer on the substrate.

According to still yet another aspect of the present disclosure, the buffer layer growing, the channel auxiliary layer growing, the channel layer growing, the lower layer growing, the light emitting layer growing, and the upper layer growing may be performed in the same reaction chamber.

According to still yet another aspect of the present disclosure, the method may further include, after the etching of a partial area of the lower layer stacked in the non-luminescent area, surface-treating the exposed channel area of the channel layer.

According to still yet another aspect of the present disclosure, in the surface-treating, the surface of the exposed channel area of the channel layer may be wet-etched.

According to still yet another aspect of the present disclosure, in the surface-treating, after the wet-etching, the surface of the wet-etched channel area maybe rinsed with an acidic solution.

According to still yet another aspect of the present disclosure, in the surface-treating, the surface of the exposed channel area of the channel layer may be N2-annealed.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto.Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light emitting transistor including a luminescent area and a non-luminescent area, comprising:
a channel layer on a substrate;
a first lower pattern in the luminescent area and a second lower pattern spaced apart from the first lower pattern in the non-luminescent area, which are disposed on the channel layer;
a light emitting layer on the first lower pattern;
an upper layer on the light emitting layer;
a first electrode on the upper layer;
an insulating layer between the first lower pattern and the second lower pattern in the non-luminescent area;
a second electrode on the insulating layer; and
a third electrode on the second lower pattern.

2. The light emitting transistor of claim 1, wherein the channel layer is an intrinsic semiconductor layer,
the first lower pattern and second lower pattern are n-type semiconductor layer,
the light emitting layer is a multiple quantum well layer, and
the upper layer is a p-type semiconductor layer.

3. The light emitting transistor of claim 2, wherein the channel layer is an undoped gallium nitride layer, and
the first lower pattern and second lower pattern are n-type gallium nitride layer.

4. The light emitting transistor of claim 1, wherein a thickness of the insulating layer is less than 0.1 μm.

5. The light emitting transistor of claim 1, wherein a distance between the first lower pattern and the second lower pattern is 1 μm or more.

6. The light emitting transistor of claim 1, wherein a thickness of the channel layer is 1 to 4 μm.

7. The light emitting transistor of claim 1, futher comprising:
a channel auxiliary layer between the substrate and the channel layer;
wherein the channel auxiliary layer is of a p-type semiconductor layer.

8. The light emitting transistor of claim 7, further comprising:
a buffer layer between the channel auxiliary layer and the substrate;
wherein a p-doping concentration of the buffer layer is lower than a p-doping concentration of the channel auxiliary layer.

9. A light emitting structure, comprising:
a channel layer;
a first semiconductor layer of a first doping polarity on the channel layer, the first semiconductor layer formed with a trench extending towards the channel layer;
an insulating layer in the trench and on at least part of the channel layer;
a light emitting layer on the first semiconductor layer, the light emitting layer surrounded by the trench;
a second semiconductor layer of a second doping polarity opposite to the first doping polarity on the light emitting layer, the second semiconductor of a transparent material; and
a gate layer over at least a portion of the insulating layer in the trench, the gate layer applied with voltage to forma channel in the channel layer to enable flow of current in the first semiconductor layer for activating the light emitting layer.

10. The light emitting structure of claim 9, further comprising:
a substrate under the channel layer;
a first electrode on the second semiconductor layer; and
a second electrode on the first semiconductor layer outside the trench and separated from the gate layer, the current caused by a voltage difference between the first electrode and the second electrode.

11. The light emitting structure of claim 10, wherein the insulating layer extends between the first electrode and the second electrode.

12. The light emitting structure of claim 10, wherein the first electrode and the gate layer are separated in a direction parallel to a direction in which a surface of the channel layer extends.

13. The light emitting structure of claim 10, further comprising a channel auxiliary layer between the substrate and the channel layer, the channel auxiliary layer to prevent leakage current.

14. The light emitting structure of claim 13, wherein the channel auxiliary layer is a semiconductor of the second doping polarity.

15. The light emitting structure of claim 9, wherein the channel layer is an undoped semiconductor.

16. The light emitting structure of claim 9, wherein the gate layer in conjunction with a part of the insulating layer and a portion of the channel layer below the gate layer forming a transistor.

17. A method for manufacturing a light emitting structure, comprising:
forming a channel layer on a substrate;
forming a first semiconductor layer of a first doping polarity on the channel layer;
forming a light emitting layer on the first semiconductor layer;
forming a second semiconductor layer of a second oping polarity opposite to the first doping polarity on the light emitting layer;
removing a portion of the first semiconductor layer, a portion of the light emitting layer, and a portion of the second semiconductor layer to define a non-luminescent area;
exposing a channel area of the channel layer in the non-luminescent area;
forming an insulating layer to cover the exposed channel area; and
forming a gate layer in the channel area and on at least a portion of the first seminconductor layer in ther non-luminescent area.

18. The method of claim 17, further comprising:
forming a first electrode on the second semiconductor layer; and
forming a second electrode on the first semiconductor layer in the non-luminescent area.

19. The method of claim 17, further comprising:
forming a channel auxiliary layer on the substrate before forming the channel layer.

20. The method of claim 19, further comprising:
forming a buffer layer on the substrate before forming the channel auxiliary layer.

21. The method of claim 17, wherein the channel layer, the first semiconductor layer and the second semiconductor layer are formed in a same reaction chamber.
